(19) United States
(12) Patent Application Publication
(10) Pub. No.: US 2026/0107435 A1
(43) Pub. Date: Apr. 16, 2026

(54) SEMICONDUCTOR DEVICE AND METHOD FOR FABRICATING THE SAME

(71) Applicant: Samsung Electronics Co., Ltd., Suwon-si (KR)

(72) Inventors: Seongeun CHO, Suwon-si (KR); Taeyang PARK, Suwon-si (KR); Hyunwoo BANG, Suwon-si (KR); Youngjoon KIM, Suwon-si (KR); Taejin PARK, Suwon-si (KR); Seungjae JUNG, Suwon-si (KR)

(73) Assignee: Samsung Electronics Co., Ltd., Suwon-si (KR)

(21) Appl. No.: 19/273,811

(22) Filed: Jul. 18, 2025

(30) Foreign Application Priority Data
Oct. 15, 2024 (KR) 10-2024-0140689

(51) Int. Cl. H10B 12/00

(52) U.S. Cl. CPC H10B 12/09; H10B 12/315; H10B 12/50

(57) ABSTRACT

A method for fabricating a semiconductor device includes forming a back gate trench within an active layer, forming a back gate electrode filling an inside of the back gate trench, forming a back gate separation pattern having a first back gate separation portion on a first portion of the back gate electrode and a second back gate separation portion on a second portion of the back gate electrode, forming spacers on sidewalls of the first and second back gate separation portions, and phase-changing the spacer on the sidewall of the first back gate separation portion, selectively removing the spacer on the sidewall of the second back gate separation portion, and etching the active layer using the spacer on the first back gate separation portion as an etching mask to form a first channel pattern and a second channel pattern on both sides of the first back gate portion.

### CROSS-REFERENCE TO RELATED APPLICATION

This application claims priority to and the benefit of Korean Patent Application No. 10-2024-0140689 filed in the Korean Intellectual Property Office on Oct. 15, 2024, the entire contents of which are incorporated herein by reference.

### BACKGROUND

The present disclosure relates to a semiconductor device and a method for fabricating the same, and more particularly, to a semiconductor device including a vertical channel transistor (VCT) and a method for fabricating the same.

There is a need to increase a degree of integration of a semiconductor device to meet the demands for higher performance and lower price by consumers. Because the degree of integration of the semiconductor device is an important factor in determining a price of a product, the increased degree of integration is particularly beneficial.

Because a degree of integration of a two-dimensional or planar semiconductor device is mainly determined by an area occupied by a unit memory cell, the degree of integration of the two-dimensional or planar semiconductor device is greatly influenced by a level of fine pattern formation technology. However, because ultra-expensive equipment is generally required to refine the pattern, the degree of integration of the two-dimensional semiconductor device is increasing but still limited. Accordingly, a semiconductor device including a vertical channel transistor in which a channel extends in a vertical direction is being proposed.

### SUMMARY

One aspect of the present disclosure provides a semiconductor device and a method of fabricating the same, which can prevent a back gate electrode from being exposed or a word line from being connected over the back gate separation portion and being disconnected when a channel pattern is formed by etching the back gate separation portion together.

A method for fabricating a semiconductor device according to one aspect includes forming a back gate trench extending in a first direction within an active layer, forming a back gate electrode filling an inside of the back gate trench, the back gate electrode having a first back gate portion and a second back gate portion alternately arranged along the first direction, forming a back gate separation pattern, the back gate separation pattern having a first back gate separation portion on the first back gate portion and a second back gate separation portion on the second back gate portion, forming spacers on sidewalls of both the first back gate separation portion and the second back gate separation portion, phase-changing the spacer on the sidewall of the first back gate separation portion and selectively removing the spacer on the sidewall of the second back gate separation portion, forming a first channel pattern and a second channel pattern on respective sides of the first back gate portion by etching the active layer using the spacer on the sidewall of the first back gate separation portion as an etching mask, forming a first word line next to the first channel pattern, forming a second word line next to the second channel pattern, and forming bit lines spaced apart in the first direction and extending in the second direction under the first channel pattern and the second channel pattern.

A method for fabricating a semiconductor device according to another aspect includes forming a back gate trench extending in a first direction within an active layer, forming a back gate electrode filling an inside of the back gate trench, the back gate electrode having a first back gate portion and a second back gate portion alternately arranged along the first direction, forming a back gate separation pattern, the back gate separation pattern having a first back gate separation portion on the first back gate portion and a second back gate separation portion on the second back gate portion, forming a spacer on sidewalls of both the first back gate separation portion and the second back gate separation portion, the spaced including a photoresist, developing the spacer on the sidewall of the first back gate separation portion and selectively removing the spacer on the sidewall of the second back gate separation portion, forming a first channel pattern and a second channel pattern on both sides of the first back gate portion by etching the active layer using the developed spacer on the sidewall of the first back gate separation portion as an etching mask, forming a first word line next to the first channel pattern and forming a second word line next to the second channel pattern, and forming bit lines such that the bit lines are spaced apart in the first direction and extend in a second direction under the first channel pattern and the second channel pattern, the second direction different from the first direction.

A semiconductor device according to another aspect includes bit lines spaced apart in a first direction and extending in a second direction different from the first direction; a first word line and a second word line on the bit lines, the first and second word lines extending in a first direction, and are alternately spaced apart from each other in a second direction; a first channel pattern and a second channel pattern on the bit line, the first and second channel pattern spaced apart in the first direction, and between the first word line and the second word line, the first channel pattern on the first word line side and the second channel pattern on the second word line side; a back gate electrode on the bit line, extending in the first direction, and having a first back gate portion disposed between the first channel pattern and the second channel pattern and a second back gate portion disposed between the first word line and the second word line; and a gate insulation pattern having a first gate insulation portion arranged between the first word line and the first channel pattern and between the second word line and the second channel pattern, and a second gate insulation portion arranged between the first word line and the second back gate portion and between the second word line and the second back gate portion, wherein the second gate insulation portion is located on the second back gate portion.

According to embodiments, when forming a channel pattern, the back gate separation portions may be protected from being etched together to expose the back gate electrode and/or the word line from being connected over the back gate separation portion and/or being disconnected. In addition, by etching only the upper portion of the back gate separation portion when forming the channel pattern, the back gate electrode can be covered by the gate insulation pattern and the gate separation pattern to secure a distance from the contact pattern.

### BRIEF DESCRIPTION OF THE DRAWINGS

FIG. 1 is a plan view of a semiconductor device according to at least one example embodiment.

FIG. 2 is a cross-sectional view taken along lines A-A and B-B of FIG. 1.

FIG. 3 is an enlarged cross-sectional view of portions P and Q of FIG. 2.

FIG. 4 is a cross-sectional view of a semiconductor device according to at least one example embodiment, corresponding to FIG. 2.

FIG. 5 is an enlarged cross-sectional view of portions P and Q of FIG. 4.

FIGS. 6 to 23 are drawings for explaining a method for fabricating a semiconductor device according to at least one example embodiment.

FIGS. 24 to 28 are drawings for explaining a method for fabricating a semiconductor device according to at least one example embodiment, and are drawings corresponding to FIGS. 8 to 12.

### DETAILED DESCRIPTION OF THE EMBODIMENTS

Hereinafter, various embodiments of the present disclosure will be described in detail with reference to the attached drawings so that a person having ordinary skill in the art to which the present disclosure pertains can easily implement the present disclosure. The present disclosure may be embodied in many different forms and is not limited to the embodiments set forth herein.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., may be exaggerated for clarity. In addition, in the drawings, for better understanding and ease of description, the thickness of some layers and areas is exaggerated. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper surface of the object portion based on a gravitational direction. Additionally, spatially relative terms, such as upper, lower, side, etc. are represented based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means viewing a target portion from the top, and the phrase “on a cross-section” means viewing a cross-section formed by vertically cutting a target portion from the side.

In addition, throughout the specification, two directions parallel to and intersecting the upper surface of the substrate are defined as the first direction D1 and the second direction D2, respectively, and the direction perpendicular to the upper surface of the substrate is described as the third direction D3. For example, the first direction D1 and the second direction D2 may be perpendicular to each other.

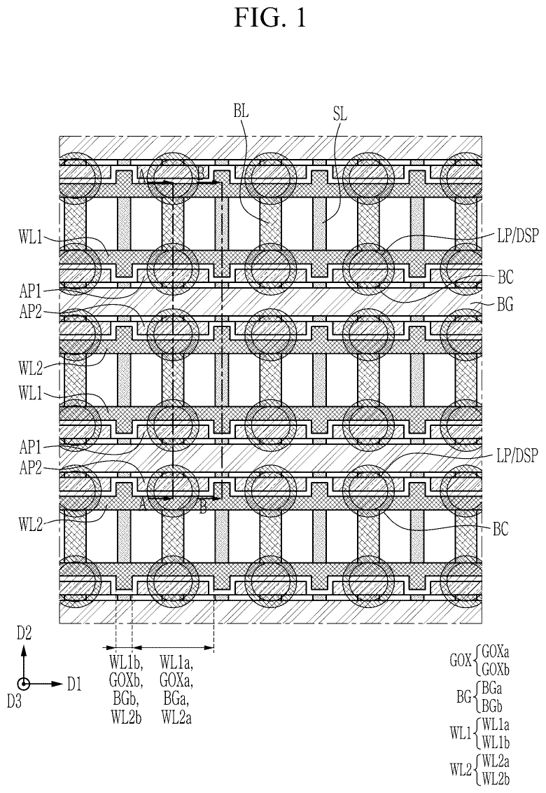

FIG. 1 is a plan view of a semiconductor device according to at least one example embodiment.

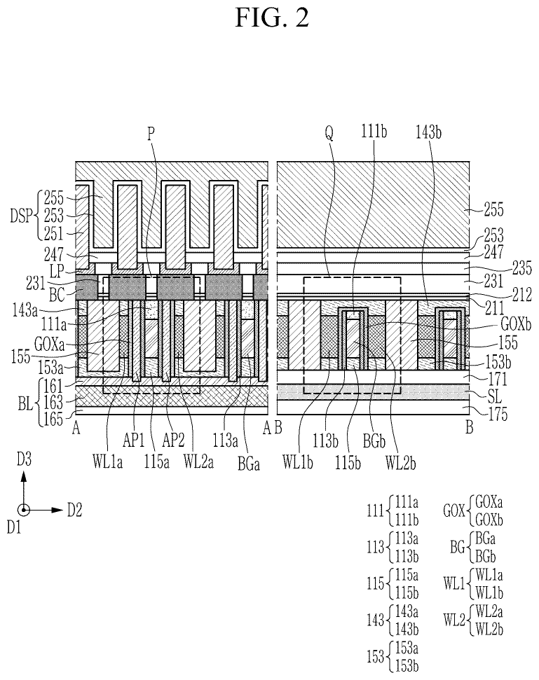

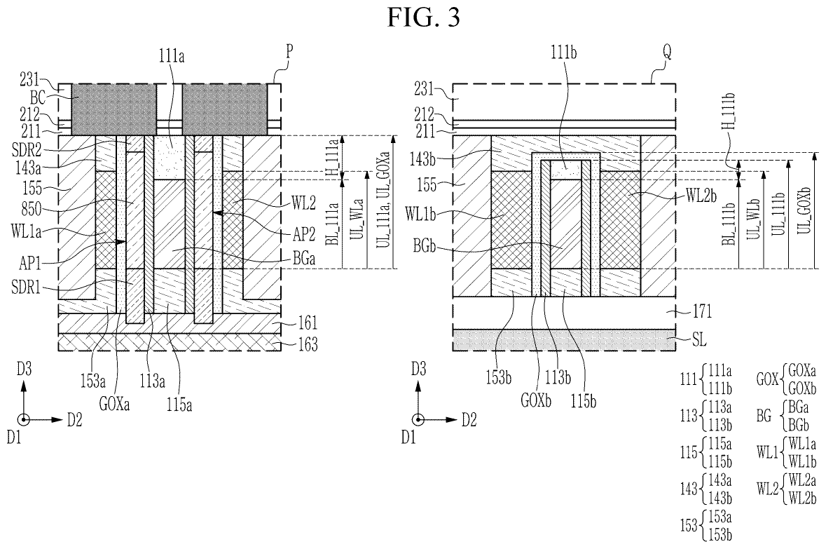

FIG. 2 is a cross-sectional view taken along lines A-A and B-B of FIG. 1. FIG. 3 is an enlarged cross-sectional view of portions P and Q of FIG. 2.

Referring to FIGS. 1 to 3, the semiconductor device includes a bit line BL, a first word line WL1 and a second word line WL2, a back gate electrode BG, a first channel pattern AP1 and a second channel pattern AP2, and a contact pattern BC.

A substrate (not illustrated) may be located under (e.g., in a third direction D3) the bit line BL. For example, the substrate may include a cell array region and a peripheral circuit region. Memory cells may be arranged on the substrate in the cell array region. As an example, a semiconductor device may include memory cells including vertical channel transistors VCTs.

The substrate may include a semiconductor material. For example, the substrate may be a silicon substrate, and/or may include other materials, such as, but not limited to, silicon germanium, indium antimonide, lead telluride, indium arsenide, indium phosphide, gallium arsenide, or gallium antimonide.

The bit line BL may be extended in a second direction D2. Neighboring bit lines BL may be spaced apart in a first direction D1. A bit line BL may include a bit line mask pattern 165, a metal pattern 163, and a polysilicon pattern 161 sequentially stacked in a third direction D3; however, the examples are not limited thereto. For example, unlike the drawings, in at least some example embodiments, the bit line BL may include only one of the polysilicon pattern 161 and the metal pattern 163.

The bit line BL may include a conductive bit line. The conductive bit line includes a film made of a conductive material among the bit lines BL. The conductive bit line may include the polysilicon pattern 161 and the metal pattern 163.

The metal pattern 163 includes a conductive material (e.g., a zero-bandgap material), and may include, for example, a conductive metal nitride, a conductive metal silicon nitride, a metal carbonitride, a conductive metal silicide, a conductive metal oxide, a two-dimensional material, a metal, and/or a combination thereof. The bit line mask pattern 165 may include an insulating material such as silicon nitride or silicon oxynitride.

According to at least some example embodiments, bit line shielding structures 171, SL, and 175 may be placed adjacent to the bit line BL. The bit line shielding structures 171, SL, and 175 may be arranged adjacent to the bit line BL in the first direction D1. That is, the bit line shielding structures 171, SL, and 175 are placed between adjacent bit lines BL in the first direction D1. The bit line shielding structures 171, SL, and 175 may extend in the second direction D2. According to at least some example embodiments, the bit line shielding structures 171, SL, and 175 may be in contact with the bit line BL.

The bit line shielding structures 171, SL, and 175 may include a bit line shielding conductive pattern SL and bit line shielding insulation films 171 and 175. The bit line shielding insulation films 171 and 175 may include a bit line shielding insulation liner 171 and a bit line shielding insulation capping film 175.

The bit line shielding insulation films 171 and 175 may wrap around the perimeter of a bit line shielding conductive pattern SL. In other words, the bit line shielding conductive pattern SL may be placed inside or in-between the bit line shielding insulation films 171 and 175.

The bit line shielding conductive pattern SL may include a conductive material (zero-bandgap material), and may include, for example, a conductive metal nitride, a conductive metal silicon nitride, a metal carbonitride, a conductive metal silicide, a conductive metal oxide, a two-dimensional material, a metal, or a combination thereof.

The bit line shielding insulation liner 171 and the bit line shielding insulation capping film 175 may each be made of an insulating material. When the bit line shielding insulation liner 171 and the bit line shielding insulation capping film 175 include the same material, the boundary between the bit line shielding insulation liner 171 and the bit line shielding insulation capping film 175 may not be distinguished.

By placing a bit line shielding structures 171, SL, and 175 between adjacent bit lines BL in the first direction D1, coupling noise between the bit lines BL may be reduced.

According to at least some example embodiments, the first channel pattern AP1 and the second channel pattern AP2 are arranged on the bit line BL. The first channel pattern AP1 and the second channel pattern AP2 may be alternately arranged along the second direction D2.

The first channel pattern AP1 may be spaced apart from each other in the first direction D1. The first channel pattern AP1 may be spaced at regular intervals. The second channel pattern AP2 may be spaced apart from each other in the first direction D1. The second channel pattern AP2 may be spaced at regular intervals. That is, the first channel pattern AP1 and the second channel pattern AP2 may be two-dimensionally arranged along the first direction D1 and the second direction D2 intersecting each other.

The first channel pattern AP1 and the second channel pattern AP2 may each have a length in the first direction D1, a width in the second direction D2, and a height in the third direction D3.

The first channel pattern AP1 and the second channel pattern AP2 may have a body portion extending in a third direction D3 and a protrusion portion protruding in the third direction D3 from the lower end of the body portion. The protrusion is located within the bit line BL, and the bit line BL can surround at least a portion of the protrusion. Accordingly, a contact area between the first channel pattern AP1 and the second channel pattern AP2 and the bit line BL can increase, thereby reducing the contact resistance.

The first channel pattern AP1 and the second channel pattern AP2 may have first and second surfaces facing each other in the third direction D3. Here, the first surface of the first channel pattern AP1 and the second channel pattern AP2 may be the lower surface, and the second surface of the first channel pattern AP1 and the second channel pattern AP2 may be the upper surface.

For example, the first surface of the first channel pattern AP1 and the second channel pattern AP2 may be in contact with the polysilicon pattern 161 of the bit line BL. Additionally, according to at least some example embodiments, unlike the drawings, when the polysilicon pattern 161 is omitted, the first surfaces of the first channel pattern AP1 and the second channel pattern AP2 can come into contact with the metal pattern. The second surfaces of the first channel pattern AP1 and the second channel pattern AP2 may be in contact with the contact pattern BC.

The first channel pattern AP1 and the second channel pattern AP2 may include first sidewalls and second sidewalls facing each other in the second direction D2. The second sidewall of the first channel pattern AP1 may face the first sidewall of the second channel pattern AP2.

A first sidewall of the first channel pattern AP1 may face the back gate electrode BG, and a second sidewall of the first channel pattern AP1 may be adjacent to the first word line WL1. A second sidewall of the second channel pattern AP2 may be adjacent to the back gate electrode BG, and a first sidewall of the second channel pattern AP2 may be adjacent to a second word line WL2.

According to at least some example embodiments, the first channel pattern AP1 and the second channel pattern AP2 may be made of a single crystal semiconductor material, and for example, the first channel pattern AP1 and the second channel pattern AP2 may each be made of single crystal silicon.

According to at least some example embodiments, each of the first channel pattern AP1 and the second channel pattern AP2 may have a first dopant region SDR1 adjacent to the bit line BL and a second dopant region SDR2 adjacent to the contact pattern BC, respectively. That is, the first dopant region SDR1 may be located at the bottom of the third direction D3 of the first channel pattern AP1 and the second channel pattern AP2, and the second dopant region SDR2 may be located at the top of the third direction D3 of the first channel pattern AP1 and the second channel pattern AP2. The first channel pattern AP1 and the second channel pattern AP2 may include a channel region 850 between the first dopant region SDR1 and the second dopant region SDR2.

The first dopant region SDR1 and the second dopant region SDR2 may be regions doped with impurities within the first channel pattern AP1 and the second channel pattern AP2. The impurity concentrations in the first dopant region SDR1 and the second dopant region SDR2 may be greater than the impurity concentrations in the channel region 850 of the first channel pattern AP1 and the second channel pattern AP2.

For example, the impurity may be an n-type impurity or a p-type impurity. According to at least some example embodiments, the n-type impurity may include phosphorus (P), arsenic (As), antimony (Sb), or a combination thereof; and the p-type impurity may include boron (B), aluminum (Al), gallium (Ga), indium (In), or a combination thereof.

Unlike the drawings, each of the first channel pattern AP1 and the second channel pattern AP2 may not include at least one of the first dopant region SDR1 and the second dopant region SDR2.

When the semiconductor device is in operation, the channel region 850 of the first channel pattern AP1 and the second channel pattern AP2 may be controlled by the first word line WL1 and the second word line WL2 and the back gate electrode BG. Since the first channel pattern AP1 and the second channel pattern AP2 are made of a single crystal semiconductor material, the leakage current characteristics of the semiconductor device may be improved.

The back gate electrode BG may be located on the bit line BL and bit line shielding structures 171, SL, and 175. The back gate electrode BG may be spaced apart from each other in the second direction D2. The back gate electrode BG may be spaced apart at regular intervals. The back gate electrode BG may extend in the first direction D1 across the bit line BL.

The back gate electrode BG may be adjacent to a first sidewall of the first channel pattern AP1 and may be adjacent to a second sidewall of the second channel pattern AP2. The back gate electrode BG may be arranged between a pair of first channel patterns AP1 and second channel pattern AP2 alternately arranged in the second direction D2. Additionally, the back gate electrode BG may be located between two pairs of first channel patterns AP1 and second channel patterns AP2 adjacent to each other in the second direction D2.

In other words, based on a pair of first channel patterns AP1 and second channel pattern AP2, the back gate electrode BG may be adjacent to a first sidewall of the first channel pattern AP1, and the back gate electrode BG may be adjacent to a second sidewall of the second channel pattern AP2. Additionally, the back gate electrode BG may be adjacent to a first sidewall of a first channel pattern AP1 belonging to one pair and may be adjacent to a second sidewall of a second channel pattern AP2 belonging to the other pair. That is, the back gate electrode BG may be located between the first channel pattern AP1 belonging to one pair and the second channel pattern AP2 belonging to the other pair. The back gate electrode BG may be adjacent to a second sidewall of a second channel pattern AP2 belonging to one pair and may be adjacent to a second sidewall of a first channel pattern AP1 belonging to the other pair. That is, the back gate electrode BG may be located between the second channel pattern AP2 belonging to one pair and the first channel pattern AP1 belonging to the other pair. For example, a back gate electrode BG, a second channel pattern AP2, a second word line WL2, a word line separation structure 155, a first word line WL1, a first channel pattern AP1, a back gate electrode BG, a second channel pattern AP2, a second word line WL2, a word line separation structure 155, a first word line WL1, and a first channel pattern AP1 may be sequentially arranged in a second direction D2, and this arrangement may be repeated in the second direction D2.

According to at least some example embodiments, the back gate electrode BG may have a first back gate portion BGa and a second back gate portion BGb. The first back gate portion BGa and the second back gate portion BGb may be alternately arranged in the first direction D1. The first back gate portion BGa and the second back gate portion BGb may be adjacent and not spaced apart in the first direction D1. In other words, the first back gate portion BGa and the second back gate portion BGb may be alternately arranged adjacent to each other in the first direction D1 to form a back gate electrode BG that extends long in the first direction D1.

As described below, the first channel pattern AP1 and the second channel pattern AP2 are spaced apart from each other in the first direction D1, and the back gate electrode BG is elongated in the first direction D1 between the first channel pattern AP1 and the second channel pattern AP2, so that the back gate electrode BG alternately passes through the channel arrangement region where the first channel pattern AP1 and the second channel pattern AP2 are located and the channel non-arrangement region where the first channel pattern AP1 and the second channel pattern AP2 are not located in the first direction D1. At this time, the first back gate portion BGa may be located in a channel arrangement region, and the second back gate portion BGb may be located in a channel non-arrangement region.

In other words, the first back gate portion BGa may be located between the first channel pattern AP1 and the second channel pattern AP2. The second back gate portion BGb may be arranged between the first word line WL1 and the second word line WL2, for example, the second back gate portion BGb may be arranged between the second word line portions WL1b and WL2b described below.

Additionally, the first back gate portion BGa may be located on the bit line BL, and the second back gate portion BGb may be located on the bit line shielding structures 171, SL, and 175.

The back gate electrode BG may have a first surface and a second surface facing in the third direction D3. The first surface of the back gate electrode BG is closer to the bit line BL than the second surface of the back gate electrode BG. In other words, the first surface of the back gate electrode BG may be the lower surface, and the second surface of the back gate electrode BG may be the upper surface.

According to at least some example embodiments, the length of the back gate electrode BG in the third direction D3 may be smaller than the lengths of the first channel pattern AP1 and the second channel pattern AP2 in the third direction D3. The length of the back gate electrode BG in the third direction D3 may be equal to or less than the lengths of the first word line WL1 and the second word line WL2 in the third direction D3.

The back gate electrode BG may include a conductive material, and may include, for example, doped polysilicon, a conductive metal nitride, a conductive metal silicon nitride, a metal carbonitride, a conductive metal silicide, a conductive metal oxide, a two-dimensional material, a metal, or a combination thereof.

When a semiconductor device is operated, a voltage is applied to the back gate electrode BG, so that the threshold voltage of the vertical channel transistor may be controlled. The threshold voltage of the vertical channel transistor may be adjusted to prevent (or safeguard against) the leakage current characteristics from deteriorating.

A back gate separation pattern 111 may be located between the first channel pattern AP1 and the second channel pattern AP2 adjacent in the second direction D2. The back gate separation pattern 111 may extend in the first direction D1 parallel to the back gate electrode BG. The back gate separation pattern 111 may be located on the second side of the back gate electrode BG.

For example, the back gate separation pattern 111 may have a first back gate separation portion 111a and a second back gate separation portion 111b.

The first back gate separation portion 111a and the second back gate separation portion 111b may be alternately arranged in the first direction D1. The first back gate separation portion 111a and the second back gate separation portion 111b may be adjacent and not spaced apart in the first direction D1. In other words, the first back gate separation portion 111a and the second back gate separation portion 111b may be alternately arranged adjacent to each other in the first direction D1 to form a back gate separation pattern 111 that extends long in the first direction D1.

The first back gate separation portion 111a may be located in a channel arrangement region, and the second back gate separation portion 111b may be located in a channel non-arrangement region. In other words, the first back gate separation portion 111a may be located between the first channel pattern AP1 and the second channel pattern AP2. The second back gate separation portion 111b may be located between the first word line WL1 and the second word line WL2, for example, the second back gate separation portion 111b may be located between the second word line portions WL1b and WL2b.

Additionally, the first back gate separation portion 111a may be located on the bit line BL, and the second back gate separation portion 111b may be located on the bit line shielding structures 171, SL, and 175.

The first back gate separation portion 111a may extend in a third direction D3 along the first sidewall of the first channel pattern AP1 on the first back gate portion BGa and may extend in a third direction D3 along the second sidewall of the second channel pattern AP2.

The first surface of the first back gate separation portion 111a may be in contact with the second surface of the first back gate portion BGa. The second surface of the first back gate separation portion 111a may be in contact with the contact pattern BC.

As described below, the first gate insulation portion GOXa is not located on the first back gate separation portion 111a. The first gate insulation portion GOXa does not cover the second surface of the first channel pattern AP1 and the second channel pattern AP2 nor the second surface of the first back gate separation portion 111a.

The second back gate separation portion 111b may extend in the third direction D3 along the sidewall of the second back gate insulation portion 113b described later on the second back gate portion BGb, and may extend in the third direction D3 along the sidewall of the second gate insulation portion GOXb.

The first surface of the second back gate separation portion 111b may be in contact with the second surface of the second back gate portion BGb. As described below, the second gate insulation portion GOXb may be disposed on the second back gate separation portion 111b. Therefore, the second surface of the second back gate separation portion 111b may be in contact with the second gate insulation portion GOXb. The second back gate separation portion 111b may be located between the second back gate portion BGb and the second gate insulation portion GOXb in the third direction D3. Accordingly, the second back gate separation portion 111b may be spaced apart from the contact pattern BC in the third direction D3.

The back gate separation pattern 111 may have a first surface and a second surface facing in the third direction D3. The first surface of the back gate separation pattern 111 is closer to the bit line BL than the second surface. In other words, the first surface of the back gate separation pattern 111 may be the lower surface, and the second side of the back gate separation pattern 111 may be the upper surface.

According to at least some example embodiments, the length of the second back gate separation portion 111b in the third direction D3 may be shorter than the length of the first back gate separation portion 111a in the third direction D3. Alternatively, the length of the second back gate separation portion 111b in the third direction D3 may be substantially the same as (or substantially similar to) the length of the first back gate separation portion 111a in the third direction D3.

For example, a ratio of the length of the second back gate separation portion 111b in the third direction D3 to the length of the first back gate separation portion 111a in the third direction D3 may be about 0.5 or more to 1, for example, about 0.6 or more to 1, about 0.7 or more to 1, about 0.8 or more to 1, or about 0.9 or more to 1, and/or about 1 or less to 1. For example, the ration may be less than about 1:1, about 0.9 or less: 1, about 0.8 or less: 1, about 0.7 or less: 1, or about 0.6 or less: 1, and about 0.5:1 to about 1:1, for example, about 0.5:1 to less than about 1:1, and/or about 0.5:1 to about 0.9:1.

Here, the length of the second back gate separation portion 111b in the third direction D3 may be the shortest distance from the first surface to the second surface of the second back gate separation portion 111b in the third direction D3. The length of the first back gate separation portion 111a in the third direction D3 may be the shortest distance from the first surface to the second surface of the first back gate separation portion 111a in the third direction D3.

For example, with respect to the first surface of the back gate electrode BG, the upper level UL_111b of the second back gate separation portion 111b in the third direction D3 may be lower than the upper level UL_111a of the first back gate separation portion 111a in the third direction D3.

The upper level UL_111b in the third direction D3 of the second back gate separation portion 111b may be lower than the upper level UL_GOXb in the third direction D3 of the second gate insulation portion GOXb.

The upper level UL_111a in the third direction D3 of the first back gate separation portion 111a may be equal to or higher than the upper level UL_GOXa in the third direction D3 of the first gate insulation portion GOXa.

The upper level UL_111a in the third direction D3 of the first back gate separation portion 111a may be higher than the upper level UL_WLa in the third direction D3 of the first word line portions WL1a and WL2a of the first word line WL1 and the second word line WL2.

The lower level BL_111a in the third direction D3 of the first back gate separation portion 111a may be lower than the upper level UL_WLa in the third direction D3 of the first word line portions WL1a and WL2a of the first word line WL1 and the second word line WL2.

The upper level UL_111b in the third direction D3 of the second back gate separation portion 111b may be higher than the upper level UL_WLb in the third direction D3 of the second word line portions WL1b and WL2b of the first word line WL1 and the second word line WL2.

The lower level BL_111b in the third direction D3 of the second back gate separation portion 111b may be lower than the upper level UL_WLb in the third direction D3 of the second word line portions WL1b and WL2b of the first word line WL1 and the second word line WL2.

As described below, when the active layer 202 is etched to form the first channel pattern AP1 and the second channel pattern AP2, if the second back gate separation portion 111b is etched together, the back gate electrode BG may be exposed or the second word line portions WL1b and WL2b may be connected to the upper portion of the second back gate separation portion 111b without being disconnected.

Further, as described below, according to at least one example embodiment, the spacer 301 located on the sidewall of the first back gate separation portion 111a is phase-changed, the spacer 301 located on the sidewall of the second back gate separation portion 111b that is not phase-changed is selectively removed, and the spacer 302 located on the sidewall of the first back gate separation portion 111a that is not removed by phase-changing is used as an etching mask to etch the active layer 202 to form a first channel pattern AP1 and a second channel pattern AP2, so that the second back gate separation portion 111b is substantially not etched and/or only an upper portion thereof is etched when etching the active layer 202. In other words, the upper portion of the second back gate separation portion 111b may be etched slightly more than the upper portion of the first back gate separation portion 111a.

Accordingly, the height of the second back gate separation portion 111b is increased, so that the back gate electrode BG is prevented (or protected) from being exposed; and/or the second word line portions WL1b and WL2b are prevented (or protected) from being connected to the upper portion of the second back gate separation portion 111b and not being disconnected.

In addition, by etching only a portion of the upper portion of the second back gate separation portion 111b or etching at least slightly more than the upper portion of the first back gate separation portion 111a, the height of the second back gate separation portion 111b in the third direction D3 becomes lower than the height of the first back gate separation portion 111a in the third direction D3, and the second back gate portion BGb and the second back gate separation portion 111b are covered by the second gate insulation portion GOXb and the second gate separation portion 143b to secure a distance from the contact pattern BC in the third direction D3.

The back gate separation pattern 111 may include an insulating material, for example, a silicon oxide film, a silicon oxynitride film, or a silicon nitride film.

The back gate insulation pattern 113 may be located between the back gate electrode BG and the first channel pattern AP1 and between the back gate electrode BG and the second channel pattern AP2. The back gate insulation pattern 113 may be located between the back gate separation pattern 111 and the first channel pattern AP1, and between the back gate separation pattern 111 and the second channel pattern AP2.

For example, the back gate insulation pattern 113 may have a first back gate insulation portion 113a and a second back gate insulation portion 113b.

The first back gate insulation portion 113a and the second back gate insulation portion 113b may be alternately arranged in the first direction D1. The first back gate insulation portion 113a and the second back gate insulation portion 113b may be alternately arranged adjacent to each other in the first direction D1 to form a back gate insulation pattern 113 that extends long in the first direction D1.

The first back gate insulation portion 113a may be located in a channel arrangement region, and the second back gate insulation portion 113b may be located in a channel non-arrangement region.

In other words, the first back gate insulation portion 113a may be located between the first back gate portion BGa and the first channel pattern AP1 and between the first back gate portion BGa and the second channel pattern AP2. The first back gate insulation portion 113a may be located between the first word line portions WL1a and WL2a and the second back gate portion BGb.

The second back gate insulation portion 113b may be located between the first word line WL1 and the second back gate portion BGb and between the second word line WL2 and the second back gate portion BGb. The second back gate insulation portion 113b may be located between the second word line portions WL1b and WL2b and the second back gate portion BGb.

Additionally, the first back gate insulation portion 113a may be located on the bit line BL, and the second back gate insulation portion 113b may be located on the bit line shielding structures 171, SL, and 175.

The first back gate insulation portion 113a may extend in a third direction D3 along the second sidewall of the first channel pattern AP1 and may extend in a third direction D3 along the first sidewall of the second channel pattern AP2.

The first surface of the first back gate insulation portion 113a may be in contact with the polysilicon pattern 161 of the bit line BL. The second surface of the first back gate insulation portion 113a may be in contact with the contact pattern BC.

The first back gate insulation portion 113a is divided, in the second direction D2, with the first back gate separation portion 111a therebetween. The first back gate insulation portion 113a does not extend in the second direction D2 on to the second surface of the first back gate separation portion 111a. In other words, the first back gate insulation portion 113a is not located on the first back gate separation portion 111a. The first back gate insulation portion 113a does not cover the second surface of the first back gate separation portion 111a.

The second back gate insulation portion 113b may extend in the third direction D3 along the first sidewall of the second back gate portion BGb and may extend in the third direction D3 along the second sidewall of the second back gate portion BGb.

The first surface of the second back gate insulation portion 113b may be in contact with the bit line shielding insulation liner 171. As described below, since the second gate insulation portion GOXb extends in the second direction D2 over the second surface of the second back gate insulation portion 113b and is located on the second back gate separation portion 111b, the second surface of the second back gate insulation portion 113b may be in contact with the second gate insulation portion GOXb. Additionally, the second surface of the second back gate insulation portion 113b may not be in contact with the contact pattern BC.

The second back gate insulation portion 113b is spaced apart in the second direction D2 with the second back gate separating portion 111b therebetween. In other words, the second back gate insulation portion 113b does not extend in the second direction D2 on the second surface of the second back gate separation portion 111b. The second back gate insulation portion 113b is not located on the second back gate separation portion 111b. The second back gate insulation portion 113b does not cover the second surface of the second back gate separation portion 111b.

The back gate insulation pattern 113 may include an insulating material, for example, a silicon oxide film, a silicon oxynitride film, a high-k insulation film having a higher dielectric constant than the silicon oxide film, or a combination thereof.

A back gate capping pattern 115 may be located between the bit line BL and the back gate electrode BG. A back gate capping pattern 115 may be located between the first channel pattern AP1 and the second channel pattern AP2 adjacent in the second direction D2. The back gate capping pattern 115 may extend in the first direction D1 parallel to the back gate electrode BG. The back gate capping pattern 115 may be located on the first surface of the back gate electrode BG. The thickness (e.g., in the third direction) of the back gate capping pattern 115 between the bit lines BL may be different from the thickness (e.g., in the third direction) of the back gate capping pattern 115 on the bit lines BL.

For example, the back gate capping pattern 115 may have a first back gate capping portion 115a and a second back gate capping portion 115b.

The first back gate capping portion 115a and the second back gate capping portion 115b may be alternately arranged in the first direction D1. The first back gate capping portion 115a and the second back gate capping portion 115b may be adjacent and not spaced apart in the first direction D1. In other words, the first back gate capping portion 115a and the second back gate capping portion 115b may be alternately arranged adjacent to each other in the first direction D1 to form a back gate capping pattern 115 that extends long in the first direction D1.

The first back gate capping portion 115a may be located in a channel arrangement region, and the second back gate capping portion 115b may be located in a channel non-arrangement region. In other words, the first back gate capping portion 115a may be located between the first channel pattern AP1 and the second channel pattern AP2. The second back gate capping portion 115b may be located between the first word line WL1 and the second word line WL2, and for example, the second back gate capping portion 115b may be located between the second word line portions WL1b and WL2b described below.

Additionally, the first back gate capping portion 115a may be located on the bit line BL, and the second back gate capping portion 115b may be located on the bit line shielding structures 171, SL, and 175.

The back gate capping pattern 115 may include an insulating material, for example, a silicon oxide film, a silicon oxynitride film, a silicon nitride film, or a combination thereof.

The first word line WL1 and the second word line WL2 may be arranged on the bit line BL and the bit line shielding structures 171, SL, and 175. Each of the first word line WL1 and the second word line WL2 may extend in the first direction D1. The first word line WL1 and the second word line WL2 may be arranged alternately in the second direction D2.

The first word line WL1 may be arranged next to the second sidewall of the first channel pattern AP1, and the second word line WL2 may be arranged next to the first sidewall of the second channel pattern AP2.

The first word line WL1 may be arranged to correspond to the back gate electrode BG with the first channel pattern AP1 therebetween. That is, the first channel pattern AP1 may be located between the first word line WL1 and the back gate electrode BG. In other words, a first word line WL1 may be arranged next to a second sidewall of the first channel pattern AP1, and a back gate electrode BG may be arranged next to a first sidewall of the first channel pattern AP1.

The second word line WL2 may be arranged to correspond to the back gate electrode BG with the second channel pattern AP2 therebetween. That is, the second channel pattern AP2 may be located between the second word line WL2 and the back gate electrode BG. In other words, a second word line WL2 may be arranged next to a first sidewall of a second channel pattern AP2, and a back gate electrode BG may be arranged next to a second sidewall of the second channel pattern AP2.

For example, a back gate electrode BG, a second channel pattern AP2, a second word line WL2, a gate separation pattern GSS, a first word line WL1, a first channel pattern AP1, a back gate electrode BG, a second channel pattern AP2, a second word line WL2, a word line separation structure 155, a first word line WL1, and a first channel pattern AP1 may be sequentially arranged in a second direction D2, and this arrangement may be repeated in the second direction D2.

The first word line WL1 and the second word line WL2 may be spaced apart from the bit line BL and the contact pattern BC in a third direction D3. That is, the first word line WL1 and the second word line WL2 may be located between the bit line BL and the contact pattern BC.

Each of the first word line WL1 and the second word line WL2 may have a width in the second direction D2. The width of the first word line WL1 and the width of the second word line WL2 on the bit line BL may be different from the width of the first word line WL1 and the width of the second word line WL2 on the bit line shielding structures 171, SL, and 175.

For example, the first word line WL1 and the second word line WL2 may each have first word line portions WL1a and WL2a and second word line portions WL1b and WL2b.

The first word line portions WL1a and WL2a and the second word line portions WL1b and WL2b may be alternately arranged in the first direction D1. The first word line portions WL1a and WL2a and the second word line portions WL1b and WL2b may be adjacent and not spaced apart in the first direction D1. In other words, the first word line portions WL1a and WL2a and the second word line portions WL1b and WL2b may be alternately arranged adjacent to each other in the first direction D1 to form the first word line WL1 and the second word line WL2 that extend long in the first direction D1.

The first word line portions WL1a and WL2a may be located in a channel arrangement region, and the second word line portions WL1b and WL2b may be located in a channel non-arrangement region. In other words, the first word line portions WL1a and WL2a may be located between the first channel pattern AP1 and the word line separation structure 155. The first word line portions WL1a and WL2a may be located between the second channel pattern AP2 and the word line separation structure 155. The second word line portions WL1b and WL2b may be located between the second back gate portion BGb and the word line separation structure 155.

Additionally, the first word line portions WL1a and WL2a may be located on the bit line BL, and the second word line portions WL1b and WL2b may be located on the bit line shielding structures 171, SL, and 175.

For example, the width of the first word line portions WL1a and WL2a in the second direction D2 may be smaller than the width of the second word line portions WL1b and WL2b in the second direction D2.

The first word line WL1 and the second word line WL2 may have a first surface and a second surface facing in the third direction D3. The first surfaces of the first word line WL1 and the second word line WL2 are closer to the bit line BL than the second surfaces of the first word line WL1 and the second word line WL2. In other words, the first surface of the first word line WL1 and the second word line WL2 may be the lower surface, and the second surface of the first word line WL1 and the second word line WL2 may be the upper surface.

The first word line WL1 is explained as an example. For example, the length of the first word line WL1 in the third direction D3 may be the same as (or substantially similar to) the length of the back gate electrode BG in the third direction D3. As another example, the length of the first word line WL1 in the third direction D3 may be greater than the length of the back gate electrode BG in the third direction D3. As another example, the length of the first word line WL1 in the third direction D3 may be smaller than the length of the back gate electrode BG in the third direction D3.

For example, with respect to the first surface of the back gate electrode BG, the upper levels UL_WLa and UL_WLb of the first word line WL1 in the third direction D3 may be identical to the upper level of the back gate electrode BG in the third direction D3. As another example, the upper levels UL_WLa and UL_WLb of the first word line WL1 in the third direction D3 may be higher than the upper level of the back gate electrode BG in the third direction D3. As another example, the upper levels UL_WLa and UL_WLb of the first word line WL1 in the third direction D3 may be lower than the upper level of the back gate electrode BG in the third direction D3.

For example, with respect to the first surface of the back gate electrode BG, the lower level of the first word line WL1 in the third direction D3 may be the same as (or substantially similar to) the lower level of the back gate electrode BG in the third direction D3. As another example, with respect to the first surface of the back gate electrode BG, the lower level of the first word line WL1 in the third direction D3 may be higher than the lower level of the back gate electrode BG in the third direction D3. As another example, with respect to the first surface of the back gate electrode BG, the lower level of the first word line WL1 in the third direction D3 may be lower than the lower level of the back gate electrode BG in the third direction D3.

The first word line WL1 and the second word line WL2 include a conductive material, and may include, for example, doped polysilicon, a conductive metal nitride, a conductive metal silicon nitride, a metal carbonitride, a conductive metal silicide, a conductive metal oxide, a two-dimensional material, a metal, or a combination thereof.

A gate insulation pattern GOX may be located between the first word line WL1 and the first channel pattern AP1, and between the second word line WL2 and the second channel pattern AP2. The gate insulation pattern GOX can extend in the first direction D1 parallel to the first word line WL1 and the second word line WL2.

For example, the gate insulation pattern GOX may have a first gate insulation portion GOXa and a second gate insulation portion GOXb.

The first gate insulation portion GOXa and the second gate insulation portion GOXb may be alternately arranged in the first direction D1. The first gate insulation portion GOXa and the second gate insulation portion GOXb may be adjacent and not spaced apart in the first direction D1. In other words, the first gate insulation portion GOXa and the second gate insulation portion GOXb may be alternately arranged adjacent to each other in the first direction D1 to form a gate insulation pattern GOX that extends long in the first direction D1.

The first gate insulation portion GOXa may be located in a channel arrangement region, and the second gate insulation portion GOXb may be located in a channel non-arrangement region. In other words, the first gate insulation portion GOXa may be located between the first word line WL1 and the first channel pattern AP1 and between the second word line WL2 and the second channel pattern AP2. The first gate insulation portion GOXa may be located between the first word line portions WL1a and WL2a and the first channel pattern AP1 and between the first word line portions WL1a and WL2a and the second channel pattern AP2. The second gate insulation portion GOXb may be located between the first word line WL1 and the second back gate portion BGb and between the second word line WL2 and the second back gate portion BGb. For example, the second gate insulation portion GOXb may be located between the second word line portions WL1b and WL2b and the second back gate portion BGb and between the second word line portions WL1b and WL2b and the second back gate portion BGb.

Additionally, the first gate insulation portion GOXa may be located on the bit line BL, and the second gate insulation portion GOXb may be located on the bit line shielding structures 171, SL, and 175.

The first gate insulation portion GOXa may extend in a third direction D3 along the first sidewall of the first channel pattern AP1 and may extend in a third direction D3 along the second sidewall of the second channel pattern AP2.

The first surface of the first gate insulation portion GOXa may be in contact with a polysilicon pattern 161 of the bit line BL. The second surface of the first gate insulation portion GOXa may be in contact with the contact pattern BC.

The first gate insulation portion GOXa may be arranged between the first word line portion WL1a of the first word line WL1 and the first channel pattern AP1, and between the first word line portion WL2a of the second word line WL2 and the second channel pattern AP2.

The first gate insulation portion GOXa may be located between the first gate separation portion 143a of the gate separation pattern 143 and the first channel pattern AP1, and between the first gate separation portion 143a of the gate separation pattern 143 and the second channel pattern AP2.

The first gate insulation portion GOXa may be located between the first gate capping portion 153a of the gate capping pattern 153 and the first channel pattern AP1, and between the first gate capping portion 153a of the gate capping pattern 153 and the second channel pattern AP2.

The first gate insulation portion GOXa is spaced apart from the first back gate separation portion 111a in the second direction D2 with the first channel pattern AP1 and the second channel pattern AP2 interposed therebetween. The first gate insulation portion GOXa does not extend in the second direction D2 on the second surface of the first channel pattern AP1 and the second channel pattern AP2. The first gate insulation portion GOXa is not located on the first back gate separation portion 111a. The first gate insulation portion GOXa does not cover the second surface of the first channel pattern AP1 and the second channel pattern AP2 and the second surface of the first back gate separation portion 111a.

The second gate insulation portion GOXb may extend in the third direction D3 along the first sidewall of the second back gate portion BGb and may extend in the third direction D3 along the second sidewall of the second back gate portion BGb. The first surface of the second gate insulation portion GOXb may be in contact with a polysilicon pattern 161 of the bit line BL.

The second gate insulation portion GOXb may be arranged between the second word line portion WL1b of the first word line WL1 and the second back gate portion BGb, and between the second word line portion WL2b of the second word line WL2 and the second channel pattern AP2. The second gate insulation portion GOXb may be in contact with the first sidewall of the second back gate insulation portion 113b and may be in contact with the second sidewall of the second back gate insulation portion 113b. The second gate insulation portion GOXb may be located between the second gate separation portion 143b of the gate separation pattern 143 and the second back gate separation portion 111b, and between the second gate separation portion 143b of the gate separation pattern 143 and the second back gate separation portion 111b. The second gate insulation portion GOXb may be located between the second gate capping portion 153b of the gate capping pattern 153 and the second back gate capping portion 115b of the back gate capping pattern 115. The second gate insulation portion GOXb may be located between the second gate capping portion 153b of the gate capping pattern 153 and the second back gate insulation portion 113b.

The second gate insulation portion GOXb may extend in the second direction D2 on the second surface of the second back gate portion BGb. The second gate insulation portion GOXb may extend in the second direction D2 on the second surface of the second back gate separation portion 111b. The second gate insulation portion GOXb may extend in the second direction D2 on the second surface of the second back gate insulation portion 113b.

In other words, the second gate insulation portion GOXb may be located on the second back gate separation portion 111b. The second gate insulation portion GOXb may cover the second surface of the first channel pattern AP1 and the second back gate separation portion 111b and the second surface of the second back gate portion BGb.

As described above, when etching the active layer 202, the second back gate separation portion 111b is not substantially etched (e.g., the upper portion is etched slightly more than the upper portion of the first back gate separation portion 111a) so that the height of the second back gate separation portion 111b in the third direction D3 becomes lower than the height of the first back gate separation portion 111a in the third direction D3, and the second back gate portion BGb and the second back gate separation portion 111b are covered by the second gate insulation portion GOXb and the second gate separation portion 143b to secure a distance from the contact pattern BC in the third direction D3.

The gate insulation pattern GOX may have first and second surfaces facing each other in the third direction D3. The first surface of the gate insulation pattern GOX is closer to the bit line BL than the second surface. In other words, the first surface of the gate insulation pattern GOX may be the lower surface, and the second surface of the gate insulation pattern GOX may be the upper surface.

The upper level UL_GOXb of the second gate insulation portion GOXb in the third direction D3 may be lower than the upper level UL_GOXa of the first gate insulation portion GOXa in the third direction D3.

The gate dielectric pattern GOX may include a film including an insulating material, such as a silicon oxide film, a silicon oxynitride film, a high-k dielectric film having a higher dielectric constant than the silicon oxide film, and/or a combination thereof.

The word line separation structure 155 may be located on a bit line BL. The word line separation structure 155 may be located between a bit line BL and a contact pattern BC. The word line separation structure 155 may be in contact with the bit line BL.

The word line separation structure 155 may be located between a first word line WL1 and a second word line WL2 adjacent to each other in the second direction D2.

The word line separation structure 155 may be located between the sidewalls of the first word line WL1 and the sidewalls of the second word line WL2 facing each other.

The first word line WL1 and the second word line WL2 may be separated by a word line separation structure 155. The word line separation structure 155 may extend in a first direction D1 between the first word line WL1 and the second word line WL2.

In some embodiments, the word line separation structure 155 may include a gate separation liner and a gate separation filling film on the gate separation liner. The gate separation liner may extend along sidewalls of the first word line WL1 and the second word line WL2. The gate separation liner and the gate separation filling film may each be made of an insulating material.

The gate separation pattern 143 may be arranged between the first word line WL1 and the contact pattern BC and between the second word line WL2 and the contact pattern BC in the third direction D3. The gate separation pattern 143 may cover the second surface of the first word line WL1 and the second word line WL2.

For example, the gate separation pattern 143 may have a first gate separation portion 143a and a second gate separation portion 143b.

The first gate separation portion 143a and the second gate separation portion 143b may be alternately arranged in the first direction D1. The first gate separation portion 143a and the second gate separation portion 143b may be adjacent and not spaced apart in the first direction D1. In other words, the first gate separation portion 143a and the second gate separation portion 143b may be alternately arranged adjacent to each other in the first direction D1 to form a gate separation pattern 143 that extends long in the first direction D1.

The first gate separation portion 143a may be located in a channel arrangement region, and the second gate separation portion 143b may be located in a channel non-arrangement region. In other words, the first gate separation portion 143a may be located between the first channel pattern AP1 and the word line separation structure 155. The first gate separation portion 143a may be located between the second channel pattern AP2 and the word line separation structure 155. The second gate separation portion 143b may be located between the second back gate portion BGb and the word line separation structure 155.

Additionally, the first gate separation portion 143a may be located on the bit line BL, and the second gate separation portion 143b may be located on the bit line shielding structures 171, SL, and 175.

The first gate separation portion 143a may extend in the third direction D3 along the sidewall of the word line separation structure 155 on the first word line portions WL1a and WL2a.

A first surface of the first gate separation portion 143a may be in contact with a second surface of the first word line portions WL1a and WL2a. The second surface of the first gate separation portion 143a may be in contact with the contact pattern BC.

The first gate separation portion 143a is spaced apart in the second direction D2 with the first back gate separation portion 111a interposed therebetween. The first gate separation portion 143a does not extend in the second direction D2 to be on the second surface of the first back gate separation portion 111a. As such, the first gate separation portion 143a is not located on the first back gate portion BGa, the first gate insulation portion GOXa, and the first back gate separation portion 111a. The first gate separation portion 143a does not cover the second surface of the first back gate separation portion 111a.

The second gate separation portion 143b may extend in the third direction D3 along the sidewall of the word line separation structure 155 on the second word line portions WL1b and WL2b.

The second surface of the second gate separation portion 143b may be in contact with the second surface of the second word line portions WL1b and WL2b. The second surface of the second gate separation portion 143b may be in contact with the contact etch stop films 211 and/or the 212 or contact interlayer insulation films 231.

The second gate separation portion 143b may extend in the second direction D2 on the second surface of the second back gate portion BGb. The second gate separation portion 143b may extend in the second direction D2 on the second surface of the second back gate separation portion 111b. The second gate separation portion 143b may extend in the second direction D2 on the second surface of the second gate insulation portion GOXb.

In other words, the second gate separation portion 143b may be located on the second back gate portion BGb, the second back gate separation portion 111b, and the second gate insulation portion GOXb. The second gate separation portion 143b may be overlapped with the second back gate portion BGb, the second back gate separation portion 111b, and the second gate insulation portion GOXb in the third direction D3. The second gate separation portion 143b may cover the second surface of the second back gate portion BGb, the second surface of the second back gate separation portion 111b, and the second surface of the second gate insulation portion GOXb.

The gate separation pattern 143 may include an insulating material, for example, a silicon oxide film, a silicon oxynitride film, a silicon nitride film, or a combination thereof.

The gate capping pattern 153 may be located on a bit line BL. The gate capping pattern 153 may be located between the bit line BL and the first word line WL1 and the second word line WL2 in the third direction D3. The gate capping pattern 153 may be in contact with the bit line BL.

The gate capping pattern 153 may cover the first surface of the first word line WL1 and the second word line WL2. The first word line WL1 and the second word line WL2 are arranged on the gate capping pattern 153. The first word line WL1 and the second word line WL2 may be arranged between the gate capping pattern 153 and the contact pattern BC.

The gate capping pattern 153 may be located between the gate insulation pattern GOX and the word line separation structure 155 in the second direction D2.

The gate capping pattern 153 may extend in the first direction D1 parallel to the first word line WL1 and the second word line WL2. The gate capping pattern 153 may be located under the first surface of the first word line WL1 and the second word line WL2.

For example, the gate capping pattern 153 may have a first gate capping portion 153a and a second gate capping portion 153b.

The first gate capping portion 153a and the second gate capping portion 153b may be alternately arranged in the first direction D1. The first gate capping portion 153a and the second gate capping portion 153b may be adjacent and not spaced apart in the first direction D1. In other words, the first gate capping portion 153a and the second gate capping portion 153b may be alternately arranged adjacent to each other in the first direction D1 to form a gate capping pattern 153 that extends long in the first direction D1.

The first gate capping portion 153a may be located in a channel arrangement region, and the second gate capping portion 153b may be located in a channel non-arrangement region. In other words, the first gate capping portion 153a may be located between the first channel pattern AP1 and the word line separation structure 155. The first gate capping portion 153a may be located between the second channel pattern AP2 and the word line separation structure 155. The second gate capping portion 153b may be located between the first word line WL1 and the second word line WL2, and the second gate capping portion 153b may be located between the second back gate portion BGb and the word line separation structure 155.

Additionally, the first gate capping portion 153a may be located on the bit line BL, and the second gate capping portion 153b may be located on the bit line shielding structures 171, SL, and 175.

For example, a width of the first gate capping portion 153a in the second direction D2 may be smaller than a width of the second gate capping portion 153b in the second direction D2.

The gate capping pattern 153 may include an insulating material. The gate capping pattern 153 may include, for example, a silicon oxide film, a silicon oxynitride film, a silicon nitride film, or a combination thereof.

The contact pattern BC may be arranged on the first channel pattern AP1 and the second channel pattern AP2. The contact pattern BC may be connected to each of the first channel pattern AP1 and the second channel pattern AP2. For example, the contact pattern BC may be connected to the second surface of the first channel pattern AP1 and the second channel pattern AP2.

The contact pattern BC includes a conductive material, and may include, for example, doped polysilicon, a conductive metal nitride, a conductive metal silicon nitride, a metal carbonitride, a conductive metal silicide, a conductive metal oxide, a two-dimensional material, a metal, and/or a combination thereof.

Each contact pattern BC can have various shapes on a plane, such as a circle, an oval, a rectangle, a square, a rhombus, a hexagon, and/or the like.

According to at least some example embodiments, contact etch stop films 211 and 212 and a contact interlayer insulation film 231 may be sequentially laminated on the gate separation pattern 143 and the back gate separation pattern 111. The contact etch stop films 211 and 212 may include a lower contact etch stop film 211 and an upper contact etch stop film 212. Unlike the drawings, the contact etch stop film may be a single film.

According to at least some example embodiments, the contact interlayer insulation film 231, the lower contact etch stop film 211, and the upper contact etch stop film 212 may each be made of an insulating material.

The contact pattern BC may penetrate the contact interlayer insulation film 231 and the contact etch stop films 211 and 212. Alternatively, at least one of the contact interlayer insulation film 231, the lower contact etch stop film 211, and the upper contact etch stop film 212 may not be disposed on the gate separation pattern 143 and the back gate separation pattern 111. In these cases, a contact separation pattern (not shown) may be located between the contact patterns (BC). The contact separation pattern may be made of an insulating material.

For example, the contact pattern BC may include a lower contact pattern and an upper contact pattern. The lower contact pattern may be in contact with the first channel pattern AP1 and the second channel pattern AP2, and the upper contact pattern may be disposed on the lower contact pattern. A concentration of impurities included in the lower contact pattern may be greater than a concentration of impurities included in the upper contact pattern.

A landing pad LP may be located on the contact pattern BC. On a plane, for example in FIG. 1, the landing pad LP may have various shapes such as circular, oval, rectangular, square, diamond, hexagonal, etc. A pad separation insulation pattern may be located between landing pads LPs. On a plane, for example, in FIG. 1, the landing pads LPs may be arranged in a matrix form along a first direction D1 and a second direction D2. The upper surface of the landing pad LP may be substantially coplanar with the upper surface of the pad separation insulation pattern.

The landing pad LP may include a conductive material, which may include, for example, doped polysilicon, a conductive metal nitride, a conductive metal silicon nitride, a metal carbonitride, a conductive metal silicide, a conductive metal oxide, a two-dimensional material, a metal, or a combination thereof. Additionally, an insulating layer 235 may be disposed around the landing pads LP. For example, the insulating layer 235 may insulate the landing pads from each other. In at least some example embodiments, the insulating layer 235 may be omitted.

Data storage patterns (DSPs) may be located on each landing pad LP. The data storage pattern DSP may be electrically connected to each of the first channel pattern AP1 and the second channel pattern AP2. The data storage patterns DSPs may be arranged in a matrix form along the first direction D1 and the second direction D2, as illustrated in FIG. 1. The data storage pattern DSP may be fully or partially overlapped with the landing pad LP in the third direction D3. The data storage pattern DSP may contact all or part of the upper surface of the landing pad LP.

For example, the data storage pattern DSP may be a capacitor. The data storage pattern DSP may include a capacitor dielectric film 253 interposed between the storage electrode 251 and the plate electrode 255. In these cases, the storage electrode 251 may be in contact with the landing pad LP. On a plane, for example, in FIG. 1, the storage electrode 251 may have various shapes such as circular, oval, rectangular, square, diamond, or hexagonal. The data storage pattern DSP may be fully or partially overlapped with the landing pad LP. The data storage pattern DSP may contact all or part of the upper surface of the landing pad LP. The storage electrode 251 may penetrate the upper etch stop film 247. The upper etch stop film 247 may be made of an insulating material.

Alternatively, the data storage pattern DSP may be a variable resistance pattern that may be switched between two resistance states by electrical pulses applied to the memory elements. For example, the data storage pattern DSP may include phase-change materials, perovskite compounds, transition metal oxides, magnetic materials, ferromagnetic materials, or antiferromagnetic materials whose crystal state changes depending on the amount of electric current.

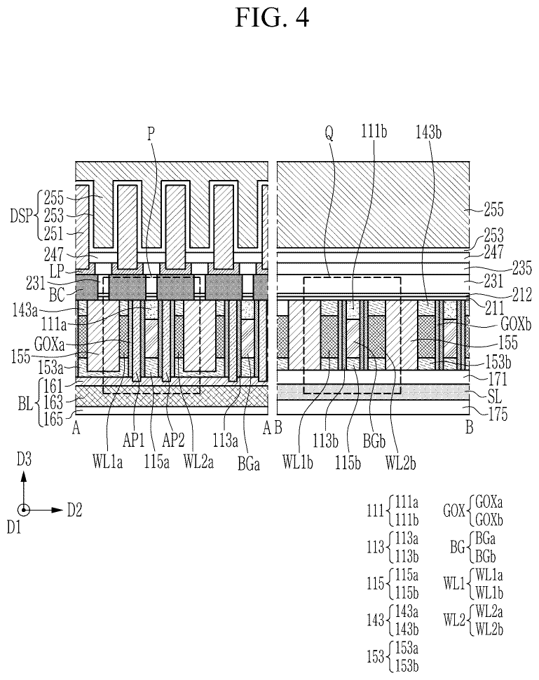

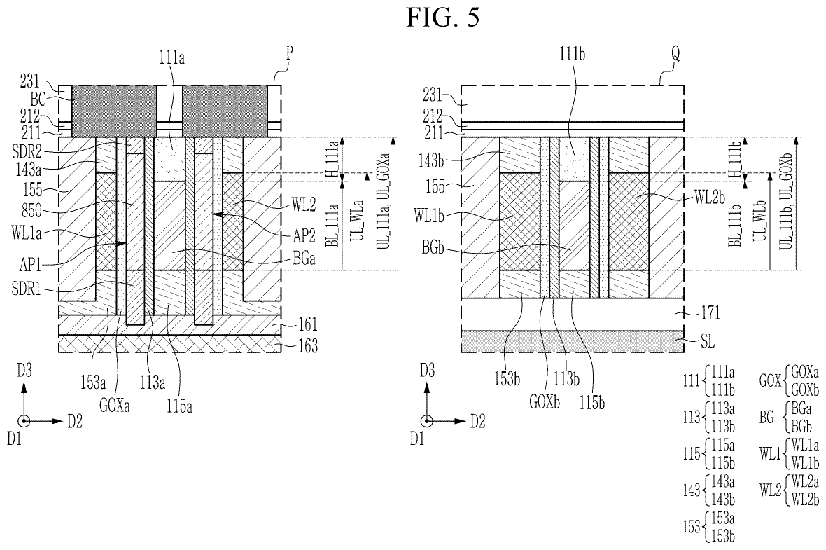

FIG. 4 is a cross-sectional view of a semiconductor device according to at least one example embodiment, corresponding to FIG. 2. FIG. 5 is an enlarged cross-sectional view of portions P and Q of FIG. 4.

For convenience of explanation, the explanation will focus on differences from those explained using FIGS. 1 to 3.

Referring to FIGS. 4 and 5, the second gate insulation portion GOXb may extend in the third direction D3 along the sidewall of the second back gate insulation portion 113b on the second back gate portion BGb, and may extend in the third direction D3 along the sidewall of the second gate insulation portion GOXb.

A first surface of the second gate insulation portion GOXb may be in contact with a second surface of the second back gate portion BGb. The second surface of the second gate insulation portion GOXb may be in contact with the contact pattern BC.

In other words, the second gate insulation portion GOXb is not located on the second back gate separation portion 111b. The second gate insulation portion GOXb does not cover the second surface of the second back gate separation portion 111b.

For example, a length of the second back gate separation portion 111b in the third direction D3 may be substantially the same as (or substantially similar to) a length of the first back gate separation portion 111a in the third direction D3. For example, a ratio of the length of the second back gate separation portion 111b in the third direction D3 to a length of the first back gate separation portion 111a in the third direction D3 may be about 1:1.

For example, with respect to the first surface of the back gate electrode BG, the upper level UL_111b in the third direction D3 of the second back gate separation portion 111b may be substantially the same as (or substantially similar to) the upper level UL_111a in the third direction D3 of the first back gate separation portion 111a.

As described above, when the second back gate separation portion 111b is not substantially etched when etching the active layer 202, the upper level of the second back gate separation portion 111b in the third direction D3 may be substantially the same as (or substantially similar to) the upper level of the first back gate separation portion 111a in the third direction.

As described later, when forming the first word line WL1 and the second word line WL2, the word line material film pWL is applied, and the word line material film pWL located on the first back gate separation portion 111a and the second back gate separation portion 111b is removed to separate the nodes, thereby forming the first word line WL1 and the second word line WL2. In this case, if the length of the second back gate separation portion 111b in the third direction D3 is sufficiently secured, there is no need to deeply etch the word line material film pWL to separate the nodes, and therefore, the length of the first word line WL1 and the second word line WL2 in the third direction D3 may be sufficiently secured, and accordingly, the length of the channel region 850 in the third direction D3 may also be sufficiently secured.

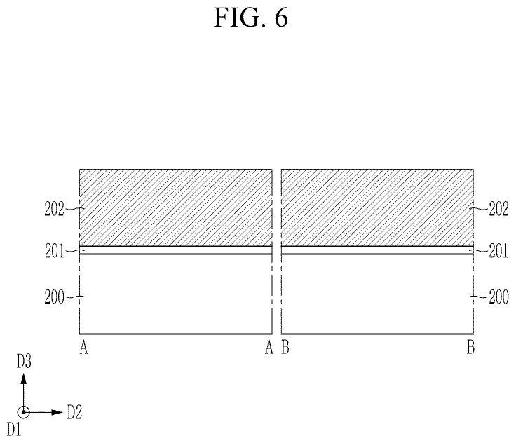

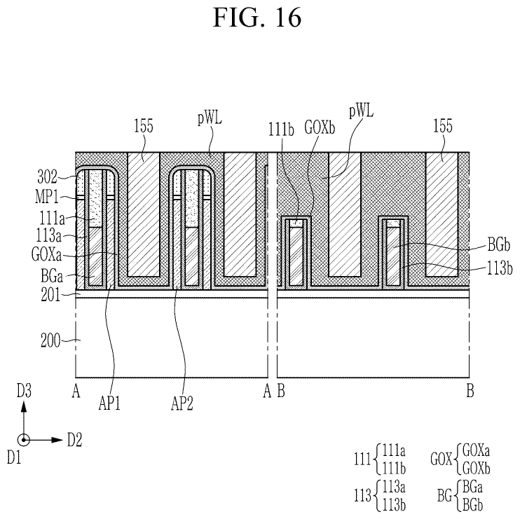

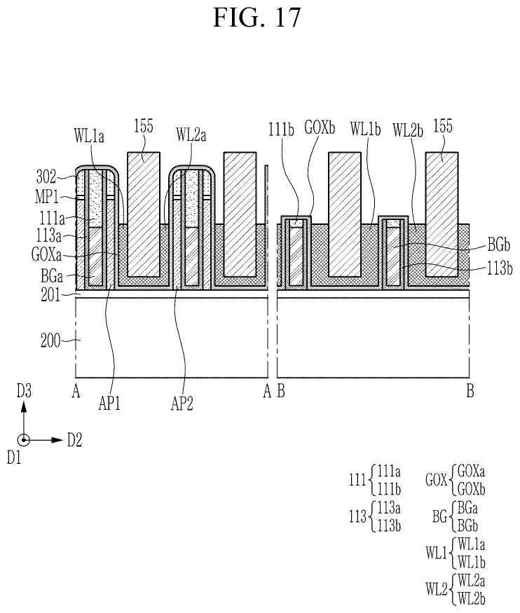

FIGS. 6 to 23 are drawings for explaining a method for fabricating a semiconductor device according to at least one example embodiment.

Referring to FIG. 6, a sub-substrate structure including a sub-substrate 200, a buried insulation layer 201, and an active layer 202 is formed.

The buried insulation layer 201 and the active layer 202 may be formed on the sub-substrate 200. For example, the sub-substrate 200, the buried insulation layer 201, and the active layer 202 may be a silicon-on-insulating material substrate (i.e., an SOI substrate).

The sub-substrate 200 may be, for example, a silicon substrate, a germanium substrate, a silicon-germanium substrate and/or the like.

The buried insulation layer 201 may be a buried oxide (BOX) formed by the separation by implanted oxygen (SIMOX) method or the bonding and layer transfer method. Alternatively, the buried insulation layer 201 may be an insulation film formed by a chemical vapor deposition method. The buried insulation layer 201 may include, for example, a silicon oxide film, a silicon nitride film, a silicon oxynitride film, and/or a low-k insulation film.

The active layer 202 may be a single crystal semiconductor film. The active layer 202 may be, for example, a single crystal silicon substrate, a germanium substrate, and/or a silicon-germanium substrate. The active layer 202 may have first and second surfaces facing each other in the third direction D3, and the second surface of the active layer 202 may be in contact with the buried insulation layer 201.

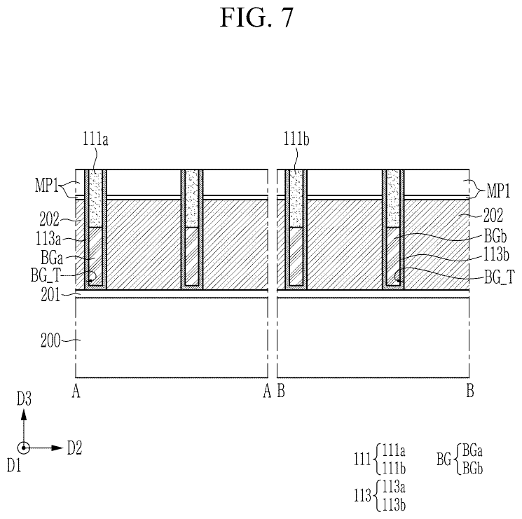

Referring to FIG. 7, the back gate electrode BG is formed within the active layer 202.

According to at least some example embodiments, first, a first mask pattern MP1 may be formed on the active layer 202. The first mask pattern MP1 may have line-shaped openings extending along the first direction D1. The first mask pattern MP1 may include a first lower mask film and a first upper mask film that are sequentially stacked. The first upper mask film may be made of a material having etch selectivity with respect to the first lower mask film. For example, the first lower mask film may include silicon oxide and the first upper mask film may include silicon nitride, but is not limited thereto.

Next, using the first mask pattern MP1 as an etching mask, the active layer 202 of the cell array region may be anisotropically etched. Accordingly, back gate trenches BG_T extending in the first direction D1 may be formed in the active layer 202 of the cell array region. The back gate trenches BG_T may expose the buried insulation layer 201 and may be spaced apart at a certain interval in the second direction D2.

Next, the back gate insulation pattern 113 and a back gate electrode BG may be formed within the back gate trench BG_T.

For example, the back gate insulation pattern 113 may be formed along the sidewall and lower surface of the back gate trench BG_T and the upper surface of the first mask pattern MP1. The back gate conductive film may be formed on the back gate insulation pattern 113. The back gate conductive film may fill the back gate trench BG_T. Next, the back gate conductive film may be isotropically etched to form a back gate electrode BG extending in the first direction D1. The back gate electrode BG may fill a portion of the back gate trench BG_T.

The back gate electrode BG may have a first back gate portion BGa and a second back gate portion BGb alternately arranged along the first direction D1. The first back gate portion BGa may be located in a channel arrangement region, and the second back gate portion BGb may be located in a channel non-arrangement region.

Additionally, the back gate insulation pattern 113 may have a first back gate insulation portion 113a located next to the first back gate portion BGa in the second direction D2 and a second back gate insulation portion 113b located next to the second back gate portion BGb in the second direction D2. In other words, the first back gate insulation portion 113a may be located in the channel arrangement region, and the second back gate insulation portion 113b may be located in the channel non-arrangement region.

Next, the back gate separation pattern 111 may be formed on the back gate electrode BG.

According to at least some example embodiments, the back gate separation pattern 111 may fill the remainder of the back gate trench BG_T. When the back gate separation pattern 111 and the back gate insulation pattern 113 are made of the same material (e.g., silicon oxide), the back gate insulation pattern 113 on the upper surface of the first mask pattern MP1 may be removed while the back gate separation pattern 111 is formed.

The back gate separation pattern 111 may have a first back gate separation portion 111a on the first back gate portion BGa in the third direction D3 and a second back gate separation portion 111b on the second back gate portion BGb in the third direction D3. In other words, the first back gate separation portion 111a may be located in a channel arrangement region, and the second back gate separation portion 111b may be located in a channel non-arrangement region.

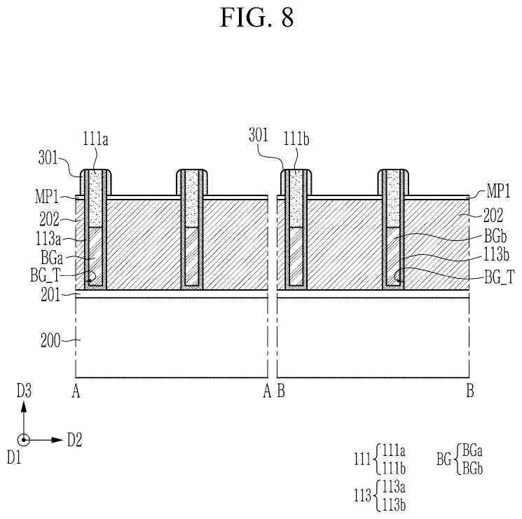

Referring to FIG. 8, spacers 301 are formed on both sidewalls of the back gate separation pattern 111 on the active layer 202.

First, after forming the back gate separation pattern 111, at least a portion of the first upper mask film MP1 may be removed. By this, the back gate separation pattern 111 may protrude above the upper surface of the first lower mask film MP1.

A spacer film may be formed along the upper surface of the first lower mask film, the sidewalls of the back gate insulation patterns 113, and the upper surface of the back gate separation pattern 111. The spacer film may be formed with a uniform thickness.

By performing an anisotropic etching process on the spacer film, a pair of spacers 301 may be formed on the sidewall of the back gate insulation pattern 113.

For example, as described below, when phase-changing of the spacer 301 using an oxidation process, the spacer 301 may include silicon (Si), silicon nitride (SiN), silicon carbide (SiC), silicon carbonitride (SiCN), and/or a combination thereof.

Alternatively, when phase-changing of the spacer 301 using a silicidation process, the spacer 301 may include titanium (Ti), cobalt (Co), nickel (Ni), and/or a combination thereof.

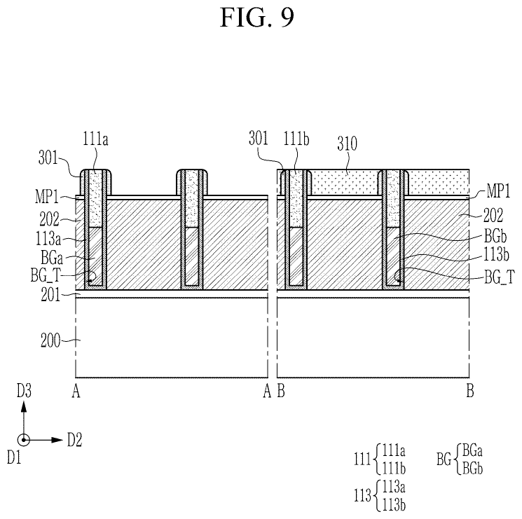

Referring to FIG. 9, a second mask pattern 310 is formed to expose a spacer 301 located on a sidewall of a first back gate separation portion 111a and cover a spacer 301 located on a sidewall of a second back gate separation portion 111b.

For example, the second mask pattern 310 may be formed by depositing silicon nitride (SiN) to cover the spacer 301 on the active layer 202 and patterning the second mask pattern 310 so as to have line-shaped openings extending along the second direction D2 in the cell array region. The openings of the second mask pattern 310 may expose the spacer 301 located on the sidewall of the first back gate separation portion 111a and cover the spacer 301 located on the sidewall of the second back gate separation portion 111b.

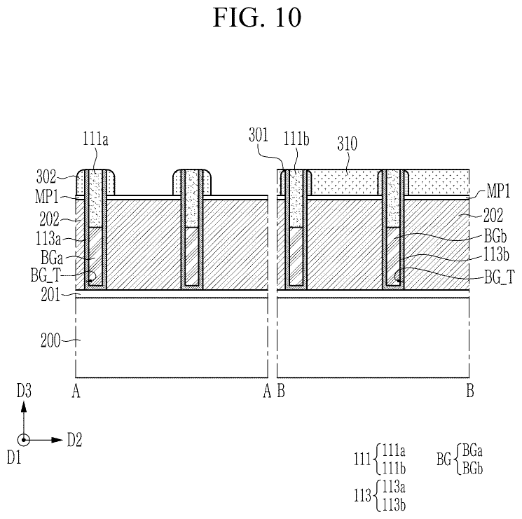

Referring to FIG. 10, a spacer 301 located on a sidewall of a first back gate separation portion 111a exposed by a second mask pattern 310 is phase-changed.

For example, the phase change of the spacer 301 may be achieved by at least one of an oxidation process or a silicidation process.

For example, when the spacer 301 includes silicon (Si), silicon nitride (SiN), silicon carbide (SiC), silicon carbonitride (SiCN), and/or a combination thereof, the spacer 301 may be phase-changed by an oxidation process. The spacer 301 may be phase-changed into silicon oxide (SiOₓ, 0<x≤2), silicon oxynitride (SiON), silicon carbonate (SiOC), silicon carbonitride (SiCON), or a combination thereof through an oxidation process.

Additionally, when the spacer 301 includes titanium (Ti), cobalt (Co), nickel (Ni), and/or a combination thereof, the spacer 301 may be phase-changed by a silicidation process. The spacer 301 may be phase-changed into titanium silicide (TiSi₂), cobalt silicide (CoSi₂), nickel silicide (NiSi), or a combination thereof by a silicidation process.

For example, the spacer 301 may increase in volume when the phase changes. For example, the phase-changed spacer 302 may have a thicker thickness in the second direction D2 than the non-phase-changed spacer 301. Depending on the thickness of the spacer 301 in the second direction D2, the widths of the first channel pattern AP1 and the second channel pattern AP2 in the second direction D2 may be determined.

When the volume of the spacer 301 increases during a phase change, the spacer film may be applied thinly to prevent the space between the back gate separation patterns 111 from being filled, while the width of the first channel pattern AP1 and the second channel pattern AP2 in the second direction D2 may be formed to be sufficiently thick.

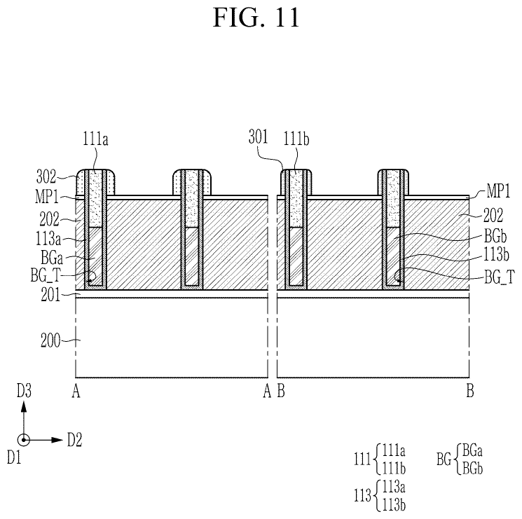

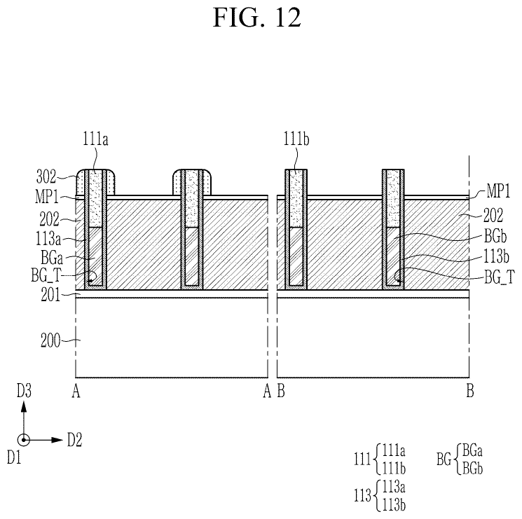

Referring to FIGS. 11 and 12, the second mask pattern 310 covering the spacer 301 located on the sidewall of the second back gate separation portion 111b is removed to expose the non-phase-changed spacer 301, and then the non-phase-changed spacer 301 may be removed.

For example, by utilizing the etching selectivity of the phase-changed spacer 302 located on the sidewall of the first back gate separation portion 111a and the non-phase-changed spacer 301 located on the sidewall of the second back gate separation portion 111b, the non-phase-changed spacer 301 may be selectively removed. For example, when the phase-changed spacer 302 includes silicon oxide (SiO₂) and the non-phase-changed spacer 301 includes silicon (Si), an etchant having a high etching selectivity of silicon (Si) with respect to silicon oxide (SiO₂) may be used.

In some other embodiments, unlike what has been described with reference to FIGS. 9 to 12, the spacer 301 located on the sidewall of the first back gate separation portion 111a may be first removed and then the spacer 301 located on the sidewall of the second back gate separation portion 111b may be phase-changed. For example, after forming a mask pattern (not shown) that exposes a spacer 301 located on a sidewall of a first back gate separation portion 111a and covers a spacer 301 located on a sidewall of a second back gate separation portion 111b, the spacer 301 located on the sidewall of the first back gate separation portion 111a may be removed. Thereafter, the mask pattern (not shown) may be removed, and the spacer 301 located on the sidewall of the second back gate separation portion 111b may be phase-changed. In these cases, the phase-changed spacer 302 may be thicker in the first direction D1 and the second direction D2 than the spacer 301 before the phase change, and accordingly, the widths of the first channel pattern AP1 and the second channel pattern AP2 in the first direction D1 and the second direction D2 may be expanded.

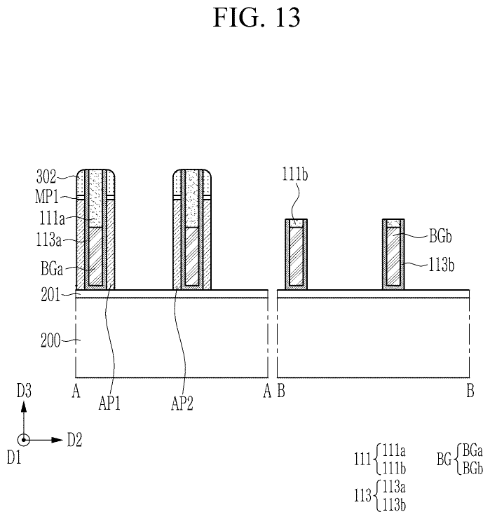

Referring to FIG. 13, the spacer 302 that remains without being removed due to phase change may be used as an etching mask to etch the active layer 202 to form a first channel pattern AP1 and a second channel pattern AP2.

For example, an anisotropic etching process for the active layer 202 may be performed using the phase-changed spacer 302 as an etching mask. Through this, a first channel pattern AP1 and a second channel pattern AP2 located on both sides of the first back gate portion BGa and the first back gate separation portion 111a may be formed, respectively. As the first channel pattern AP1 and the second channel pattern AP2 are formed, the buried insulation layer 201 is exposed, and a word line trench may be formed between the first channel pattern AP1 and the second channel pattern AP2 spaced apart in the second direction D2.

Meanwhile, after forming the first channel pattern AP1 and the second channel pattern AP2, some of the phase-changed spacer 302 may remain on the first channel pattern AP1 and the second channel pattern AP2.

As described above, when the spacer 301 located on the sidewall of the first back gate separation portion 111a is phase-changed, the spacer 301 located on the sidewall of the second back gate separation portion 111b that is not phase-changed is selectively removed, and the spacer 302 located on the sidewall of the first back gate separation portion 111a that is not removed by phase-change is used as an etching mask to etch the active layer 202 to form the first channel pattern AP1 and the second channel pattern AP2, when etching the active layer 202, the second back gate separation portion 111b may not be substantially etched or only the upper portion thereof may be etched. In other words, the upper portion of the second back gate separation portion 111b may be etched slightly more than the upper portion of the first back gate separation portion 111a.

Accordingly, the height of the second back gate separation portion 111b is greater than the height of the first back gate separation portion 111a, so that the back gate electrode BG is prevented (or shielded) from being exposed and/or the second word line portions WL1b and WL2b is prevented (or shielded) from being connected to the upper portion of the second back gate separation portion 111b and not being disconnected.

In addition, by etching only a portion of the upper portion of the second back gate separation portion 111b and/or etching at least slightly more than the upper portion of the first back gate separation portion 111a, the height of the second back gate separation portion 111b in the third direction D3 becomes lower than the height of the first back gate separation portion 111a in the third direction, and the second back gate portion BGb and the second back gate separation portion 111b may be covered by the second gate insulation portion GOXb and the second gate separation portion 143b to secure a distance from the contact pattern BC in the third direction D3.

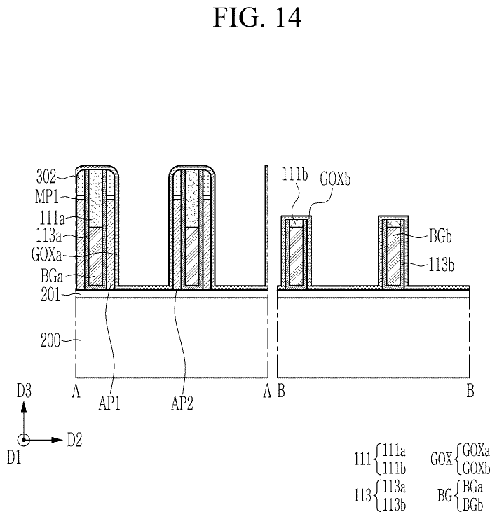

Referring to FIGS. 14 to 17, a first word line WL1 and a second word line WL2 are formed on a gate insulation pattern GOX.

First, a gate insulation pattern GOX may be formed along a sidewall of the first channel pattern AP1, a sidewall of the second channel pattern AP2, an upper surface of the first back gate separation portion 111a, a sidewall and an upper surface of the phase-changed spacer 302, an upper surface of the second back gate separation portion 111b, and a sidewall of the second back gate insulation portion 113b.

For example, the gate dielectric pattern GOX may be formed using at least one of physical vapor deposition (PVD), thermal chemical vapor deposition (thermal CVD), low-pressure chemical vapor deposition (LP-CVD), plasma-enhanced chemical vapor deposition (PE-CVD), and/or atomic layer deposition (ALD) techniques, but the examples are not limited thereto.

The gate insulation pattern GOX may have a first gate insulation portion GOXa located next to the first back gate portion BGa in the second direction D2 and a second gate insulation portion GOXb located next to the second back gate portion BGb in the second direction D2. In other words, the first gate insulation portion GOXa may be located in the channel arrangement region, and the second gate insulation portion GOXb may be located in the channel non-arrangement region.

The first gate insulation portion GOXa may be located on the sidewall of the first channel pattern AP1, the sidewall of the second channel pattern AP2, the upper surface of the first back gate separation portion 111a, and the sidewall and upper surface of the phase-changed spacer 302. The second gate insulation portion GOXb may be located on the upper surface of the second back gate separation portion 111b and the sidewall of the second back gate insulation portion 113b.

Next, a first word line WL1 and a second word line WL2 may be formed on the gate insulation pattern GOX. A first word line WL1 and a second word line WL2 may be formed next to sidewalls of the first channel pattern AP1 and the second channel pattern AP2. Additionally, it may be formed next to the sidewalls of the second back gate insulation portion 113b of the first word line WL1 and the second word line WL2.

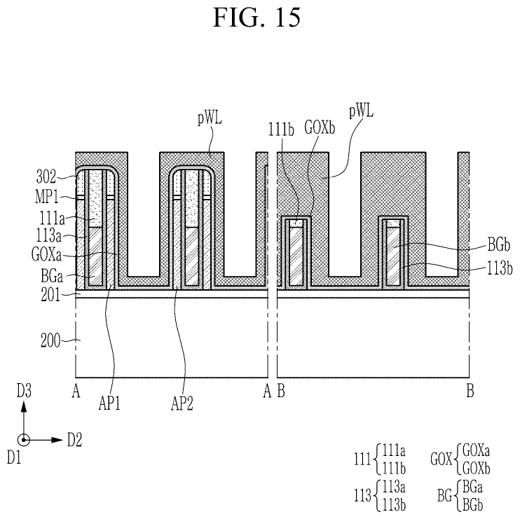

Forming the first word line WL1 and the second word line WL2 may include depositing a word line material film pWL on a gate insulation pattern GOX, filling a word line separation structure 155 within a word line trench, and performing an anisotropic etching process on the word line material film pWL. Here, the deposition thickness of the word line material film pWL may be less than half the width of the word line trench. In FIG. 15, the upper surface of the portion overlapping the first back gate portion BGa and the upper surface of the portion overlapping the second back gate portion BGb in the third direction D3 of the word line material film pWL are illustrated as located at the same level, but the present disclosure is not limited thereto. For example, when the spacing between two first channel patterns AP1 adjacent to each other in the first direction D1 and the spacing between two second channel pattern AP2 adjacent to each other in the first direction D1 are relatively narrow, the upper surface of a portion of the word line material film pWL that is overlapped with the second back gate portion BGb in the third direction D3 may be located at a higher level than the upper surface of a portion that is overlapped with the first back gate portion BGa.

A word line separation structure 155 may be formed to fill a word line trench in which a word line material film pWL is formed. The word line separation structure 155 may include, for example, a silicon nitride (SiN) film, a silicon oxynitride (SiON) film, a silicon carbide (SiC), a silicon carbonitride (SiCN) film, or a combination thereof.

During an anisotropic etching process for a word line material film pWL, a gate insulation pattern GOX may be used as an etch stop film. Unlike the drawings, the gate insulation pattern GOX may be over-etched, exposing the buried insulation layer 201.

As described above, by using the phase-changed spacer 302 as an etching mask to form the first channel pattern AP1 and the second channel pattern AP2, the second back gate separation portion 111b is substantially not etched or only an upper portion thereof is etched, so that the height of the second back gate separation portion 111b in the third direction D3 may be slightly lower than the height of the first back gate separation portion 111a in the third direction.

Accordingly, the length of the word line material film pWL formed on the second back gate separation portion 111b in the third direction D3 may be thicker than the length of the word line material film pWL formed on the first back gate separation portion 111a in the third direction D3. Therefore, etching of the word line material film pWL may proceed until the second gate insulation portion GOXb covering the second back gate separation portion 111b having a lower height is exposed.

Accordingly, the second gate insulation portion GOXb may be located on the second back gate separation portion 111b. The second gate insulation portion GOXb may cover the second surface of the second back gate separation portion 111b and the second surface of the second back gate portion BGb. On the other hand, the first gate insulation portion GOXa located on the first back gate separation portion 111a is removed, so that the first gate insulation portion GOXa is not located on the first back gate separation portion 111a.

The first word line WL1 and the second word line WL2 may each have first word line portions WL1a and WL2a located next to the first back gate portion BGa in the second direction D2 and second word line portions WL1b and WL2b located next to the second back gate portion BGb in the second direction D2. In other words, the first word line portions WL1a and WL2a may be located in a channel arrangement region, and the second word line portions WL1b and WL2b may be located in a channel non-arrangement region.

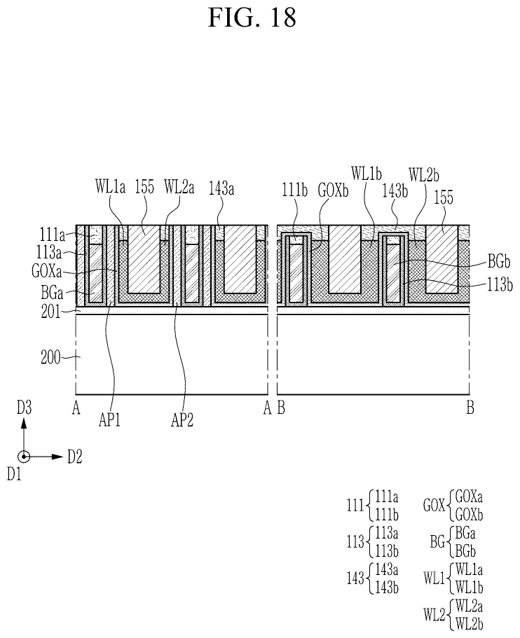

Referring to FIG. 18, a gate separation pattern 143 is formed on the first word line WL1 and the second word line WL2.

The gate separation pattern 143 may be formed in a space where the word line material film pWL has been removed. The gate separation pattern 143 may cover the first word line WL1 and the second word line WL2.

Then, a planarization process may be performed on the gate separation pattern 143 and the word line separation structure 155 so that the upper surfaces of the first channel pattern AP1 and the second channel pattern AP2 are exposed. At this time, the phase-changed spacer 302 remaining on the first channel pattern AP1 and the second channel pattern AP2 may be removed.

The gate separation pattern 143 may include, for example, a silicon nitride film (SiN), a silicon oxynitride film (SiON), a silicon carbide (SiC), a silicon carbonitride film (SiCN), and/or combinations thereof.

The gate separation pattern 143 may have a first gate separation portion 143a located next to the first back gate portion BGa in the second direction D2 and a second gate separation portion 143b located next to the second back gate portion BGb in the second direction D2. In other words, the first gate separation portion 143a may be located in the channel arrangement region, and the second gate separation portion 143b may be located in the channel non-arrangement region.

As described above, by using the phase-changed spacer 302 as an etching mask to form the first channel pattern AP1 and the second channel pattern AP2, the second back gate separation portion 111b is substantially not etched and/or only an upper portion thereof is etched, so that the height of the second back gate separation portion 111b in the third direction D3 may be slightly lower than the height of the first back gate separation portion 111a in the third direction.

Accordingly, the second gate separation portion 143b may be located on the second back gate separation portion 111b and the second gate insulation portion GOXb. The second gate separation portion 143b may cover the second surface of the second gate insulation portion GOXb, the second surface of the second back gate separation portion 111b, and the second surface of the second back gate portion BGb.

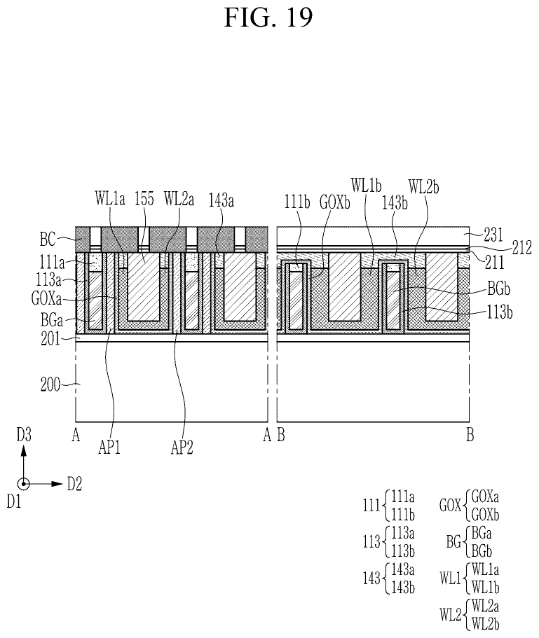

Referring to FIG. 19, a contact pattern BC is formed on the first channel pattern AP1 and the second channel pattern AP2. The contact patterns BC may be connected to the first channel pattern AP1 and the second channel pattern AP2.

For example, the contact pattern BC may be formed in an engraving manner. That is, contact etch stop films 211 and 212 and contact interlayer insulation films 231 are formed sequentially, and a contact hole penetrating them is formed, and then a contact pattern BC may be formed within the contact hole.

Alternatively, the contact pattern BC may be formed in an embossing manner. That is, a contact film that comes into contact with the first channel pattern AP1 and the second channel pattern AP2 is formed, and the contact film is patterned, so that a contact pattern BC may be formed. A contact separation pattern (not shown) may be formed between the spaced contact patterns BC.

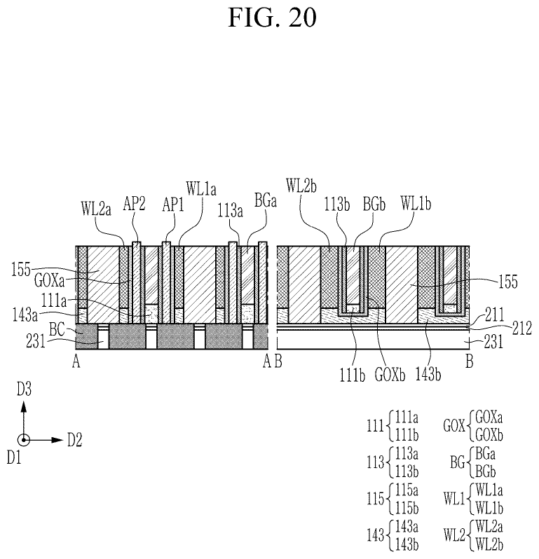

Referring to FIG. 20, after rotating the semiconductor device, the sub-substrate 200 and the buried insulation layer 201 may be removed, thereby exposing the first channel pattern AP1 and the second channel pattern AP2.

Removing of the sub-substrate 200 may include sequentially performing a grinding process and/or a wet etching process to expose the buried insulation layer 201.

Next, the buried insulation layer 201 may be removed to expose the first channel pattern AP1, the second channel pattern AP2, the first word line WL1, and the second word line WL2. Additionally, the buried insulation layer 201 may be removed, so that a portion of the gate insulation pattern GOX and a portion of the back gate insulation pattern 113 may be exposed.

For example, the upper portion of the exposed gate insulation pattern GOX and the back gate insulation pattern 113 may be selectively removed. For example, when the gate insulation pattern GOX and the back gate insulation pattern 113 include a silicon oxide film and the first channel pattern AP1 and the second channel pattern AP2 include single crystal silicon, only a portion of the gate insulation pattern GOX and the back gate insulation pattern 113 may be selectively removed.

Through this, the first channel pattern AP1 and the second channel pattern AP2 may be protruded on the second surface of the gate insulation pattern GOX and the back gate insulation pattern 113. Accordingly, the first channel pattern AP1 and the second channel pattern AP2 may have protrusions located within the bit line BL, and the contact area between the first channel pattern AP1 and the second channel pattern AP2 and the bit line BL may increase, thereby reducing the contact resistance.

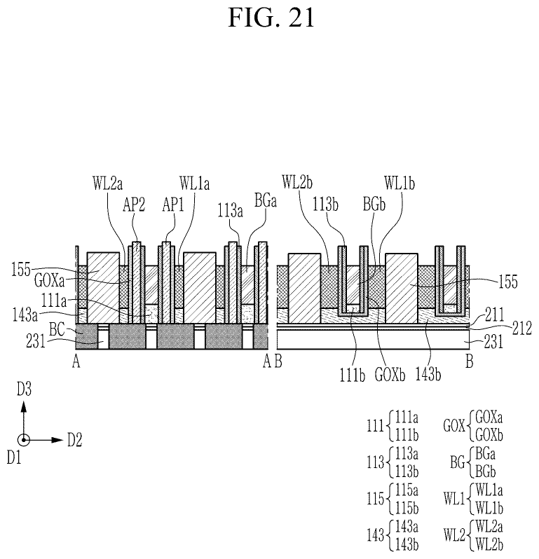

Referring to FIG. 21, a portion of the back gate electrode BG, a portion of the first word line WL1, a portion of the second word line WL2, and a portion of the word line separation structure 155 may be removed.

For example, the removal of the back gate electrode BG, the first word line WL1, the second word line WL2, and the word line separation structure 155 can utilize, e.g., an etch-back process.

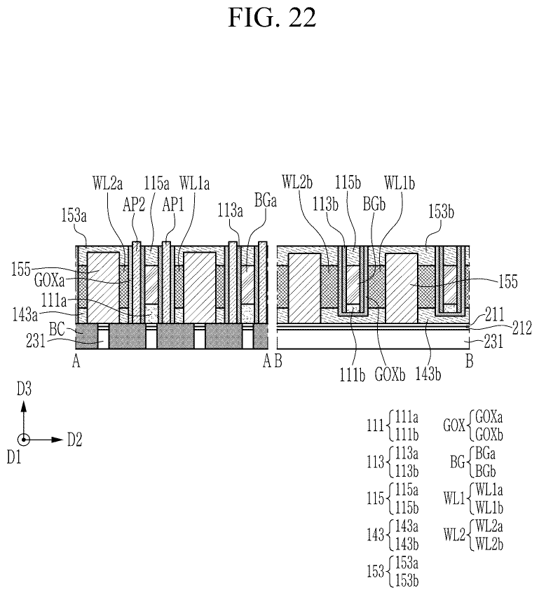

Referring to FIG. 22, a back gate capping pattern 115 may be formed on the recessed back gate electrode BG. Additionally, a gate capping pattern 153 may be formed on the recessed first word line WL1, second word line WL2, and word line separation structure 155.

For example, the back gate capping pattern 115 and the gate capping pattern 153 may be formed simultaneously.

The back gate capping pattern 115 may have a first back gate capping portion 115a on the first back gate portion BGa in the third direction D3 and a second back gate capping portion 115b on the second back gate portion BGb in the third direction D3. In other words, the first back gate capping portion 115a may be located in the channel arrangement region, and the second back gate capping portion 115b may be located in the channel non-arrangement region.

Additionally, the gate capping pattern 153 may have a first gate capping portion 153a located next to the first back gate portion BGa in the second direction D2 and a second gate capping portion 153b located next to the second back gate portion BGb in the second direction D2. In other words, the first gate capping portion 153a may be located in the channel arrangement region, and the second gate capping portion 153b may be located in the channel non-arrangement region.

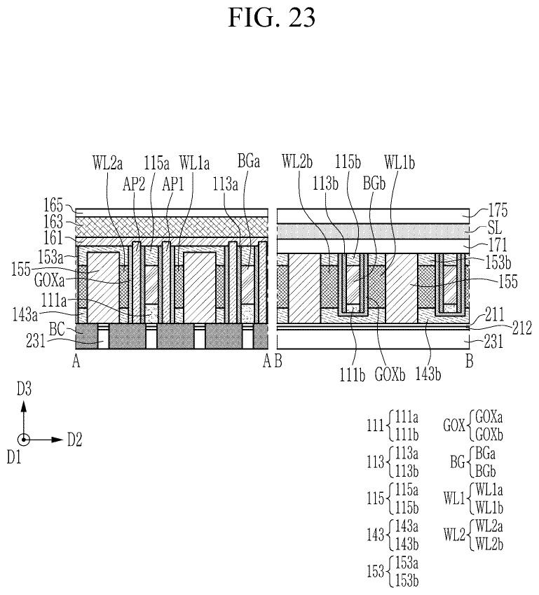

Referring to FIG. 23, a bit line BL is formed on the first channel pattern AP1 and the second channel pattern AP2.

First, a polysilicon pattern 161, a metal pattern 163, and a bit line mask pattern 165 are sequentially stacked on a first channel pattern AP1 and a second channel pattern AP2.

A bit line BL extending in the second direction D2 is formed by patterning a bit line mask pattern 165, a metal pattern 163, and a polysilicon pattern 161.

During the formation of the bit line BL, a portion of the back gate capping pattern 115 and the gate capping pattern 153 may be etched.

Next, a bit line shielding insulation liner 171 may be formed on the bit line BL. A bit line shielding insulation liner 171 may define a bit line shielding region between bit lines BL.

The bit line shielding insulation liner 171 may have a substantially uniform thickness. A bit line shielding insulation liner 171 may be formed on the front surface of the sub-substrate 200. The deposition thickness of the bit line shielding insulation liner 171 may be less than about half the distance between the bit lines BL. By forming the bit line shielding insulation liner 171, a bit line shielding region may be defined between the bit lines BL by the bit line shielding insulation liner 171. The bit line shielding region may extend in the second direction D2 parallel to the bit lines BL.

After forming the bit line shielding insulation liner 171, a bit line shielding conductive pattern SL may be formed within the bit line shielding region of the bit line shielding insulation liner 171.

The bit line shielding conductive pattern SL may be formed between each bit line BL. For example, forming of the bit line shielding conductive pattern SL may include forming a bit line shielding conductive film to fill a bit line shielding region on a bit line shielding insulation liner 171 and recessing an upper surface of the bit line shielding conductive film.

Next, a bit line shielding insulation capping film 175 may be formed on the bit line shielding conductive pattern SL.

Forming of a bit line shielding insulation capping film 175 may include forming a bit line shielding capping insulation film that fills a bit line shielding region in which a bit line shielding conductive pattern SL is formed. In addition, the forming of the bit line shielding insulation capping film 175 may include performing a planarization process on the bit line shielding capping insulation film and the bit line shielding insulation liner 171 so that the upper surfaces of the bit lines BLs (e.g., the upper surface of the bit line mask pattern 165) are exposed.

Referring again to FIG. 2, a data storage pattern DSP may be formed on the contact pattern BC.

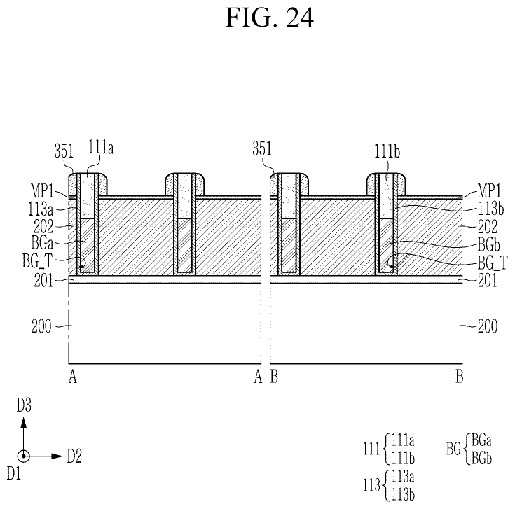

FIGS. 24 to 28 are drawings for explaining a method for fabricating a semiconductor device according to at least one example embodiment, and are drawings corresponding to FIGS. 8 to 12.

For convenience of explanation, the explanation will focus on differences from those explained using FIGS. 8 to 12.

Referring to FIG. 24, a spacer 351 including a photoresist is formed on both sidewalls of a back gate separation pattern 111 located on an active layer 202.

For example, the spacer 351 including the photoresist may be formed by coating a composition for a photoresist. For example, the coating may be formed by applying a spin coating, spray coating, dip coating, knife edge coating method, or a printing method such as inkjet printing or screen printing, and then drying the applied photoresist composition.

The photoresist may be a negative photoresist or a positive photoresist. Negative photoresists allow unexposed regions to be selectively removed, while positive photoresists allow exposed regions to be selectively removed. Below, the case of negative photoresist is explained.

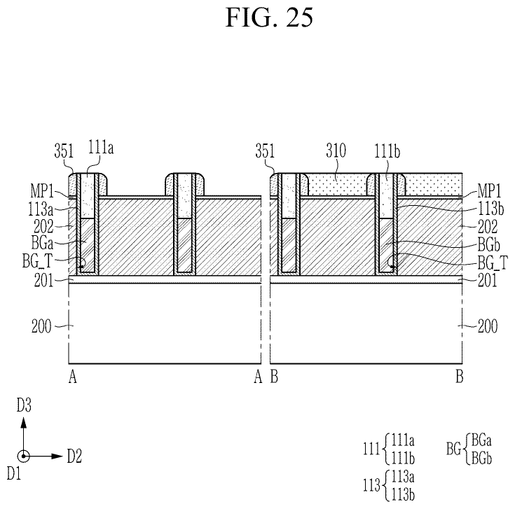

Referring to FIG. 25, a second mask pattern 310 is formed to expose a spacer 351 located on a sidewall of a first back gate separation portion 111a and cover a spacer 351 located on a sidewall of a second back gate separation portion 111b.

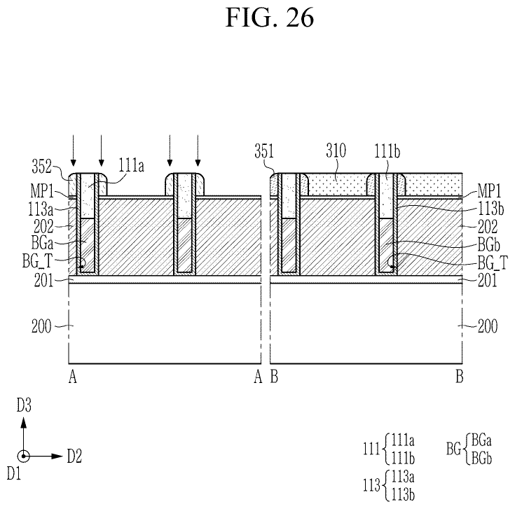

Referring to FIG. 26, a spacer 351 located on a sidewall of a first back gate separation portion 111a is exposed, and a spacer 351 located on a sidewall of a second back gate separation portion 111b is selectively removed.

For example, examples of light that may be used in the exposure process include light with short wavelengths, such as activating radiation i-line (wavelength 365 nm), krypton fluoride (KrF) excimer laser (wavelength 248 nm), and/or arsenic fluoride (ArF) excimer laser (wavelength 193 nm), as well as light with high energy wavelengths, such as EUV (Extreme UltraViolet; wavelength 13.5 nm) or E-Beam (electron beam). For example, the exposure light may be a short wavelength light having a wavelength range of about 5 nm to about 150 nm, or may be a light having a high energy wavelength such as EUV or E-Beam.

In some embodiments, a baking process may be performed on the exposed spacer 352. For example, the baking process may be performed at a temperature of about 120° C. to about 200° C. for about 30 seconds to about 3 minutes. Due to the baking process, the exposed spacer 352 becomes difficult to dissolve in the developer.

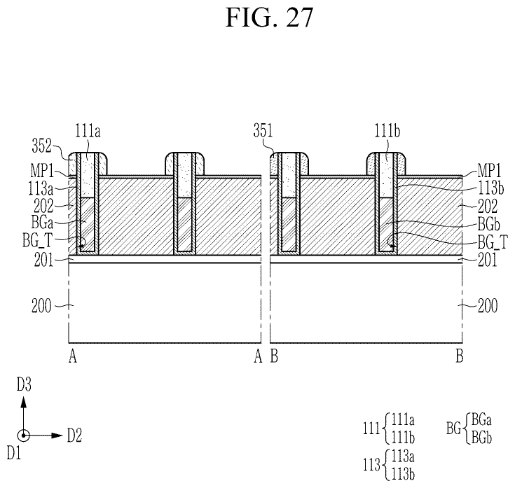

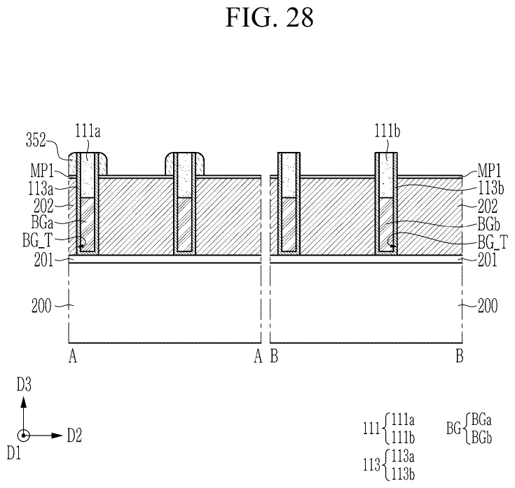

Referring to FIGS. 27 and 28, the second mask pattern 310 covering the spacer 351 located on the sidewall of the second back gate separation portion 111b is removed to expose the unexposed spacer 301, and then the unexposed spacer 351 may be removed.

For example, the unexposed spacer 351 may be selectively removed using a developer. For example, the developer may be an organic solvent, such as a ketone such as methyl ethyl ketone, acetone, cyclohexanone, 2-heptanone, or an alcohol such as 4-methyl-2-propanol, 1-butanol, isopropanol, 1-propanol, methanol, or an ester such as propylene glycol monomethyl ether acetate, ethyl acetate, ethyl lactate, n-butyl acetate, butyrolactone, or an aromatic compound such as benzene, xylene, toluene, or a combination thereof. Additionally, the developer may be an organic solvent including about 9 percentage by weight (wt %) or less of an acidic substance or a basic substance based on the total weight.

Thereafter, the active layer 202 may be etched using the spacer 352 that is not exposed and removed as an etching mask to form a first channel pattern AP1 and a second channel pattern AP2.

However, the method of forming the spacer 351 according to some embodiments is not limited to using a negative photoresist, and a positive photoresist may also be used.

In this case, the selectively removing of the spacer 351 located on the sidewall of the second back gate separation portion 111b may be accomplished by exposing (or developing) the spacer 351 located on the sidewall of the second back gate separation portion 111b, forming a second mask pattern 310 that covers the spacer 351 located on the sidewall of the first back gate separation portion 111a, exposing (or developing) the spacer 351 located on the sidewall of the second back gate separation portion 111b exposed by the second mask pattern 310, removing the second mask pattern 310, and selectively removing the spacer 352 located on the exposed sidewall of the second back gate separation portion 111b using a developer.

Developers that may be used to develop the positive photoresist include, for example, quaternary ammonium hydroxide compositions such as tetraethylammonium hydroxide, tetrapropylammonium hydroxide, tetrabutylammonium hydroxide, a combination thereof, and/or the like.

Although some example embodiments of the present disclosure have been described in detail above, the scope of the present disclosure is not limited thereto, and various modifications and improvements made by those skilled in the art using the basic concepts of the present disclosure defined in the following claims also fall within the scope of the present disclosure.

What is claimed is:

1. A method for fabricating a semiconductor device, comprising:
forming a back gate trench extending in a first direction within an active layer;
forming a back gate electrode filling an inside of the back gate trench, the back gate electrode having a first back gate portion and a second back gate portion alternately arranged along the first direction;
forming a back gate separation pattern, the back gate separation pattern having a first back gate separation portion on the first back gate portion and a second back gate separation portion on the second back gate portion;
forming spacers on sidewalls of both the first back gate separation portion and the second back gate separation portion;
phase-changing the spacer on the sidewall of the first back gate separation portion and selectively removing the spacer on the sidewall of the second back gate separation portion;
forming a first channel pattern and a second channel pattern on respective sides of the first back gate portion by etching the active layer using the spacer on the sidewall of the first back gate separation portion as an etching mask;
forming a first word line next to the first channel pattern;
forming a second word line next to the second channel pattern; and
forming bit lines such that the bit lines are spaced apart in the first direction and extend in a second direction under the first channel pattern and the second channel pattern, the second direction different from the first direction.

2. The method of claim 1, wherein the selectively removing of the spacer on the sidewall of the second back gate separation portion comprises:
forming a mask pattern exposing the spacer on the sidewall of the first back gate separation portion and covering the spacer located on the sidewall of the second back gate separation portion,
removing the mask pattern after the phase-changing the spacer on the sidewall of the first back gate separation portion exposed by the mask pattern, and
the selectively removing the spacer on the sidewall of the second back gate separation portion after the removing the mask pattern.

3. The method of claim 1, wherein
the spacer on the sidewall of the first back gate separation portion increases in volume during the phase-changing.

4. The method of claim 1, wherein
the phase-changing of the spacer includes at least one of an oxidation process or a silicidation process.

5. The method of claim 4, wherein
the spacer on the sidewall of the first back gate separation portion comprises silicon (Si) phase-changed into silicon oxide (SiOₓ, 0<x≤2), silicon nitride (SiN) phase-changed into silicon oxynitride (SiON), silicon carbide (SiC) phase-changed into silicon carbonate (SiOC), silicon carbon nitride (SiCN) phase-changed into silicon carbonitride (SiCON), or a combination thereof.

6. The method of claim 4, wherein
the spacer on the sidewall of the first back gate separation portion comprises titanium (Ti) phase-changed into titanium silicide (TiSi₂), cobalt (Co) phase-changed into cobalt silicide (CoSi₂), nickel (Ni) phase-changed into nickel silicide (NiSi), or a combination thereof.

7. The method of claim 1, wherein the forming the first channel pattern and the second channel pattern includes
etching an upper portion of the second back gate separation portion more than an upper portion of the first back gate separation portion, and
wherein, after the etching, a length of the second back gate separation portion in a third direction, which is different from the first direction and the second direction, is less than or equal to a length of the first back gate separation portion in the third direction.

8. The method of claim 1, wherein the forming of the first word line and the second word line comprises:
applying a gate insulation pattern so that the gate insulation pattern covers the back gate electrode and the first channel pattern and the second channel pattern,
covering the gate insulation pattern with a word line material film, and
etching the word line material film.

9. The method of claim 8, wherein
the forming the gate insulation pattern includes forming the gate insulation pattern such that the gate insulation pattern includes a first gate insulation portion next to the first back gate portion in the second direction and a second gate insulation portion next to the second back gate portion in the second direction, and
the etching of the word line material film is performed until the second gate insulation portion is exposed so that the second gate insulation portion is located on the second back gate portion.

10. The method of claim 9, wherein
the second back gate separation portion is located between the second back gate portion and the second gate insulation portion in a third direction, the third direction different from the first direction and the second direction.

11. The method of claim 8, wherein the etching the word line material film includes:
forming a first word line portion next to the first back gate portion in the second direction and a second word line portion next to the second back gate portion in the second direction.

12. The method of claim 11, wherein
the etching the word line material film further includes forming a gate separation pattern in a space removed by the etching of the word line material film so that the gate separation pattern has a first gate separation portion next to the first back gate portion in the second direction and a second gate separation portion next to the second back gate portion in the second direction,
the forming the gate insulation pattern includes forming the gate insulation pattern such that the gate insulation pattern includes a first gate insulation portion next to the first back gate portion in the second direction and a second gate insulation portion next to the second back gate portion in the second direction, and
the second gate separation portion is located on the second back gate portion, the second back gate separation portion, and the second gate insulation portion.

13. The method of claim 12, further comprising:
forming a word line separation structure on the word line material film;
removing, after the etching the word line material film, the spacer on the sidewall of the first back gate separation portion, and
planarizing the word line separation structure until the first channel pattern and the second channel pattern are exposed,
wherein the first gate insulation portion is not located on the first back gate portion, and
the first gate separation portion is not located on the first back gate portion, the first back gate separation portion, or the first gate insulation portion.

14. The method of claim 13, wherein, after the etching the word line material film,
an upper level of the second back gate separation portion in a third direction, different from the first direction and the second direction, is lower than an upper level of the first back gate portion in the third direction,
an upper level of the second back gate separation portion in the third direction is lower than an upper level of the second gate insulation portion in the third direction,
an upper level of the first back gate separation portion in the third direction is equal to or higher than an upper level of the first gate insulation portion in the third direction.

15. The method of claim 13, wherein, after the etching the word line material film,
an upper level of the second back gate separation portion in a third direction, different from the first direction and the second direction, is higher than upper levels of the first word line and the second word line in the third direction, and
a lower level of the second back gate separation portion in the third direction is lower than an upper level of the first word line and the second word line in the third direction.

16. The method of claim 1, further comprising:
applying a back gate insulation pattern inside the back gate trench,
wherein the back gate electrode is formed on the back gate insulation pattern,
the back gate insulation pattern comprises
a first back gate insulation portion between the first back gate portion and the first channel pattern and between the first back gate portion and the second channel pattern, and
a second back gate insulation portion between the first word line and the second back gate portion and between the second word line and the second back gate portion,
the first back gate insulation portion is not located on the first back gate portion, and
the second back gate insulation portion is not located on the second back gate portion.

17. The method of claim 1, further comprising:
forming a contact pattern on the first channel pattern and the second channel pattern such that the contact pattern is connected to the first channel pattern and the second channel pattern is further formed,
wherein the first back gate separation portion is in contact with the contact pattern, and
the second back gate separation portion is spaced apart from the contact pattern in a third direction different from the first direction and the second direction.

18. A method for fabricating a semiconductor device, comprising
forming a back gate trench extending in a first direction within an active layer;
forming a back gate electrode filling an inside of the back gate trench, the back gate electrode having a first back gate portion and a second back gate portion alternately arranged along the first direction;
forming a back gate separation pattern, the back gate separation pattern having a first back gate separation portion on the first back gate portion and a second back gate separation portion on the second back gate portion;
forming a spacer on sidewalls of both the first back gate separation portion and the second back gate separation portion, the spaced including a photoresist;
developing the spacer on the sidewall of the first back gate separation portion and selectively removing the spacer on the sidewall of the second back gate separation portion;
forming a first channel pattern and a second channel pattern on both sides of the first back gate portion by etching the active layer using the developed spacer on the sidewall of the first back gate separation portion as an etching mask ;
forming a first word line next to the first channel pattern;
forming a second word line next to the second channel pattern; and
forming bit lines such that the bit lines are spaced apart in the first direction and extend in a second direction under the first channel pattern and the second channel pattern, the second direction different from the first direction.

19. The method of claim 18, wherein
the photoresist included in the spacer is a negative photoresist, and
selectively removing the spacer located on the sidewall of the second back gate separation portion comprises
forming a mask pattern exposing the spacer on the sidewall of the first back gate separation portion and covering the spacer on the sidewall of the second back gate separation portion,
developing the spacer located on the sidewall of the first back gate separation portion and exposed by the mask pattern,
removing the mask pattern, and
selectively removing the spacer on the sidewall of the second back gate separation portion that is not developed.

20. The method of claim 18, wherein
the photoresist included in the spacer is a positive photoresist, and
selectively removing the spacer located on the sidewall of the second back gate separation portion comprises
forming a mask pattern exposing the spacer on the sidewall of the second back gate separation portion and covering the spacer on the sidewall of the first back gate separation portion
exposing the spacer on the sidewall of the second back gate separation portion and exposed by the mask pattern to a developer,
removing the mask pattern, and
selectively removing the spacer located on the sidewall of the second back gate separation portion that is exposed using the developer.
